(19) United States
(12) Patent Application Publication
(10) Pub. No.: US 2024/0240688 A1
(43) Pub. Date: Jul. 18, 2024

(54) MITIGATION OF SEISMIC EVENT EFFECTS ON LIQUID IMMERSION COOLING SYSTEMS

(71) Applicants: Phil Geng, Washougal, WA (US); Prabhakar Subrahmanyam, San Jose, CA (US); Vishnu Prasadh Sugumar, Santa Clara, CA (US); Jacob McMillian, Beaverton, OR (US); Ralph V. Miele, Hillsboro, OR (US); Ying-Feng Pang, San Jose, CA (US); David Shia, Portland, OR (US)

(72) Inventors: Phil Geng, Washougal, WA (US); Prabhakar Subrahmanyam, San Jose, CA (US); Vishnu Prasadh Sugumar, Santa Clara, CA (US); Jacob McMillian, Beaverton, OR (US); Ralph V. Miele, Hillsboro, OR (US); Ying-Feng Pang, San Jose, CA (US); David Shia, Portland, OR (US)

(21) Appl. No.: 18/620,216

(22) Filed: Mar. 28, 2024

(51) Int. Cl. F16F 9/50; G01V 1/36; H05K 7/20

(52) U.S. Cl. CPC F16F 9/50; G01V 1/36; H05K 7/20236; H05K 7/20272; H05K 7/20281; F16F 2230/08; F16F 2230/18; G01V 2210/144; G01V 2210/6222

(57) ABSTRACT

In some embodiments, an immersion cooling system comprises a spring damper, a crumple block, a frictional layer, and/or preloaded spring-based mounts to mitigate the effects of seismic events. In other embodiments, the combined mass of liquids in the immersion tank and a compensation tank is kept constant to maintain the system's response to seismic events. In still other embodiments, an immersion cooling system comprises a tunable mass to provide an active response to seismic events. In yet other embodiments, an immersion tank is located within a housing pallet and is moveable within the palette. Spring dampers dampen tank movement within the pallet and shutoff switches housed in the pallet cause power to components in the tank to be shut off in response to tank movement. Cooling liquid can be transferred from the tank to a secondary reservoir to avoid cooling liquid loss and protect the tank.

### BACKGROUND

Liquid immersion cooling offers an alternative to the cooling of computing components by air. In liquid immersion cooling, computing components are cooled via immersion in a non-conductive liquid that can efficiently absorb and dissipate heat. One drawback of liquid immersion cooling systems is their susceptibility to seismic events, such as earthquakes. The cooling liquid in the immersion tank can slosh around during a seismic event, which can lead to the loss of cooling liquid due to spillage and damage to the immersion tank and computing components located therein.

### BRIEF DESCRIPTION OF THE DRAWINGS

FIG. 1 is a block diagram of a first example immersion cooling system comprising components to mitigate the effects of seismic events on immersion cooling systems.

FIG. 2 is a block diagram of a second example immersion cooling system comprising components to mitigate the effects of seismic events on immersion cooling systems.

FIG. 3 is an example method of maintaining a constant mass of liquid in an immersion cooling system.

FIG. 4 is a block diagram of a third example immersion cooling system comprising components to mitigate the effects of seismic events on immersion cooling systems.

FIG. 5 is a block diagram of a top view of a fourth example immersion cooling system comprising components to mitigate the effects of seismic events on immersion cooling systems.

FIG. 6 is a first example method of mitigating the effects of seismic events on immersion cooling systems.

FIG. 7 is a second example method of mitigating the effects of seismic events on immersion cooling systems.

FIG. 8 is a third example method of mitigating the effects of seismic events on immersion cooling systems.

FIG. 9 is a block diagram of a fifth example immersion cooling system comprising components to mitigate the effects of seismic events on immersion cooling systems.

FIG. 10 is a perspective view of a sixth example immersion cooling system comprising components to mitigate the effects of seismic events on immersion cooling systems.

FIG. 11 is a close-up view of the sixth example immersion cooling system of FIG. 10 showing a more detailed view of a shutoff switch, a pusher plate, and spring dampers.

FIG. 12 is a perspective view of the sixth example immersion cooling system of FIG. 10 with a portion of the cooling liquid transferred from the immersion cooling tank to the secondary reservoirs.

FIG. 13 is a top view of the sixth example immersion cooling system of FIG. 10

FIG. 14 is a fourth example method of mitigating the effects of seismic events on immersion cooling systems.

FIG. 15 is a fifth example method of mitigating the effects of seismic events on immersion cooling systems.

FIG. 16 is a sixth example method of mitigating the effects of a seismic on immersion cooling systems.

FIG. 17 is a block diagram of an example computing system or computing device in which technologies described herein may be implemented.

FIG. 18 is a block diagram of an example processor unit to execute computer-executable instructions as part of implementing technologies described herein.

### DETAILED DESCRIPTION

Liquid immersion cooling (immersion cooling) involves immersing computing components in a tank of circulating non-conductive cooling liquid. In some existing solutions, immersion tanks are large enough to hold a series of printed circuit boards, with each printed circuit board comprising processors, memories, or other heat-generating electronic components. In general, liquid immersion cooling works by circulating a dielectric cooling liquid through an immersion tank and a heat exchanger. The cooling liquid absorbs heat generated by electronic components located in the tank, the heat exchanger dissipates the absorbed heat to the environment, and the cooled cooling liquid is returned to the tank to absorb more heat. In some embodiments, liquid immersion cooling can provide for increased heat removal efficiency, less power consumption, space savings, and reduced noise over air-cooled solutions due to liquid cooling not requiring fans, air conditioning systems, dedicated aisles for air circulation, and associated ductwork.

In data centers and other facilities that employ liquid immersion cooling, immersion cooling systems or assemblies need to be able to withstand (or be isolated from) the loads that they can encounter while experiencing vibrations or shocks. This need is particularly important in geographical regions where earthquakes are common. These vibration and shock-induced loads include lateral, vertical, sloshing, and impact loads. Lateral loads are horizontal forces that act on tank sidewalls and can cause them to shear or buckle. The magnitude of lateral forces depends on the intensity of a seismic event and the size and shape of the tank. Vertical loads are uplift forces that act on the bottom of the tank and can work to lift the tank off of the base on which the tank is located. These forces can be particularly important for tanks with a large bottom surface area. Sloshing loads are dynamic loads caused by the movement of cooling liquid within the tank. The sloshing of a cooling liquid can create additional stresses on the tank walls and can also cause the tank to move, fracture, leak, or tip over. Sloshing loads can further damage printed circuit boards immersed in an immersion tank and can cause cooling liquid to spill over the sides of the tank. If power is not shut down to the printed circuit boards inside an immersion cooling system damage to the boards during a seismic event can create a potential fire hazard.

Impact loads are sudden forces that can occur if the immersion cooling tank comes into contact with other objects during the earthquake. These forces can be significant and can cause localized damage to a tank. These lateral, vertical, sloshing, and impact loads can depend on various factors such as the size and depth of the immersion cooling tank (larger tanks will experience greater loads due to their larger bottom surface area and volume, and deeper tanks will experience increased hydrostatic pressure due to the larger cooling liquid volume), the type of cooling liquid used (different coolants have varying densities, which can affect the overall load on the tank), and the intensity of a seismic event (the stronger the earthquake, the greater the seismic forces acting on the immersion tank).

Some existing immersion cooling system configurations do not possess enough vibration and shock resilience to survive a significant seismic event, such as a strong earthquake. Such systems may include those in which an immersion cooling tank is rigidly attached to a wall or a floor (by, for example, a combination of columns, beams, brackets, and screws; or by brazing the tank to the wall or floor), or rests on a structure that provides only a small amount of damping, such as a polymer mat. In some existing immersion cooling systems, ball bearings can be placed under a tank to allow movement of the tank relative to the base.

These existing immersion cooling system configurations can suffer from various disadvantages. Immersion cooling tanks that are rigidly attached to a wall or a floor by screws can experience high stresses where the screws attach to the immersion cooling tank walls. While polymer mats provide a source of friction between the tank and a base, they can have a “slip-stick” effect in which a tank can experience undesirable alternating periods of slipping and sticking as it moves against the mat. And, while ball bearings reduce the friction between the tank and a base, they may not dissipate energy easily and may generate a prolonged vibration response.

Described herein are technologies that mitigate the effect of seismic events on immersion cooling systems. In some embodiments, as an immersion cooling tank loses cooling liquid to spillage while experiencing vibration or shock, liquid is added to a compensation tank that is rigidly attached to the immersion cooling tank to keep the mass of the system (and thus the natural frequency of the system) steady. In other embodiments, the immersion tank rests on a frictional layer of sand, sand-like, or other material that allows the tank to move relative to the base while also damping the movement of the tank. In other embodiments, spring dampers are mounted to an immersion tank through preloading of the spring dampers, thereby avoiding the use of screws—a source of tank damage during a seismic event—to attach the spring damper to the tank.

In other embodiments spring dampers attached to the immersion tank mitigate the effects of vibration and shocks by absorbing the energy of a tank that is moving in response to vibrations or a shock and damping the movement of the tank. Crumple blocks are another type of energy absorber that can be used to absorb the kinetic energy of a moving tank and dampen tank movement. The energy absorbers described herein can be tunable. That is, they can have their properties (e.g., a spring damper stiffness property, a spring damper dumping property) adjusted upon detection of a seismic event to provide an active response to the seismic event. In still other embodiments, a tunable mass damper system is attached to an immersion cooling tank. The tunable mass damper system comprises a tunable mass whose mass can be adjusted based on the characteristics of an active seismic event.

In other embodiments, an immersion cooling tank is located in a housing pallet and rests on a ball transfer plate to allow for movement of the tank within the housing pallet. Shutoff switches are located on walls of the housing pallet and spring dampers positioned between the immersion tank and the housing pallet walls absorb tank movement energy. If the tank moves far enough during a seismic event and activates (presses) a shutoff switch, power to components immersed in the tank is shut off and the immersion cooling system is in a safe state. The activation of a shutoff switch can further cause cooling liquid to be transferred from the immersion cooling tank to one or more secondary reservoirs located outside of the housing pallet. This transfer of cooling liquid can act to prevent the loss of cooling liquid from the immersion cooling tank due to sloshing of the liquid as well as adjusting the response of the immersion cooling tank to the vibration or shock. The cooling liquid transferred to the secondary reservoirs can be transferred back to the immersion cooling tank after expiration of a predetermined time or upon determination that the seismic event has ended.

In any of the embodiments comprising an active response to a seismic event, detection of a seismic event can be based on sensor data provided by an accelerometer or an inertial measurement unit to a controller. The controller can be located local to or remote from an immersion cooling system and the sensor data can be provided to the controller via a wireless or wired connection. In some embodiments, detecting a seismic event can be performed using a machine learning model that has been trained on sensor data corresponding to seismic events.

The seismic event mitigation technologies disclosed herein have at least the following advantages. First, they can bring an immersion cooling system into compliance with building and other codes or standards that the immersion cooling system may be subject to, such as International Building Code (IBC) and American Society of Civil Engineer (ASCE) standards. Second, they can provide responses that are tailored to the frequency characteristics of individual seismic events. This is advantageous as the distribution of an earthquake's energy across frequencies can vary across earthquakes. An immersion cooling system's response to a seismic event can be adjusted through the adjustment of immersion cooling system component properties (e.g., spring and dumping properties of tunable spring dampers, the mass of tunable mass dumping systems). The active response of an immersion cooling system can be adjusted in real-time as characteristics of a seismic event change during the seismic event. Third, vibration and shock-resilient immersion cooling systems may be able to remain operational (or remain operational for a longer time during a seismic event). This can be important if the computing components being cooled by the system are executing critical workloads. Fourth, the nature of the components of the various embodiments (e.g., pusher plate, spring damper, shutoff switch) allows for simple retrofitting of existing immersion cooling tanks without extensive rework. Fifth, by mitigating the effects of seismic events on immersion cooling tanks, data center downtime (along with the attendant repair costs) in earthquake-prone geographic can be reduced.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a first wall of a housing pallet that is substantially orthogonal to a second wall of the housing pallet includes first walls that are within several degrees of 90 degrees to the second wall, and keeping a liquid mass substantially constant includes liquid masses than are kept to within +/−5% of a value.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form to facilitate a description thereof. The intention is to cover all modifications, equivalents, and alternatives within the scope of the claims.

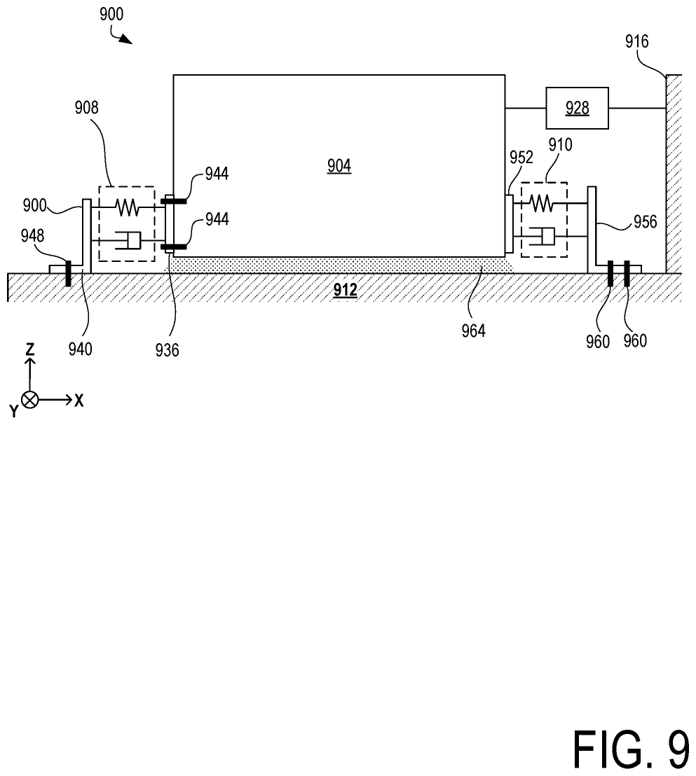

As used herein, the phrase “located on” in the context of a first layer, part, or component located on a second layer, part, or component refers to the first layer, part, or component being directly physically attached to the second layer, part, or component (no parts, layers, or components between the first and second layers, parts, or components) or physically attached to the second layer, part, or component with one or more intervening layer, part, or component. For example, with reference to FIG. 9, the tank 904 is located on the base 912 with an intervening frictional layer 964.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, FET) or a passive electronic component (e.g., resistor, inductor, capacitor).

As used herein, the terms “operating” or “executing” as they pertain to software or firmware in relation to a system, device, platform, or resource are used interchangeably and can refer to software or firmware stored in one or more computer-readable storage media accessible by the system, device, platform, or resource, even though the software or firmware instructions are not actively being executed by the system, device, platform, or resource.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

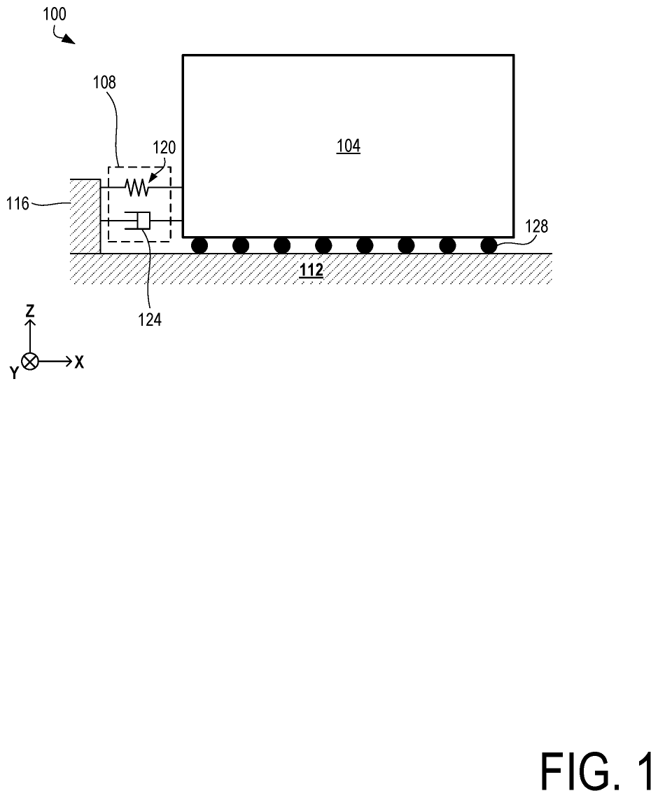

FIG. 1 is a block diagram of a first example immersion cooling system comprising components to mitigate the effects of seismic events on immersion cooling systems. The immersion cooling system 100 comprises an immersion cooling tank 104 (immersion tank) and a spring damper 108. The immersion tank 104 is located on a base 112. The spring damper 108 is attached at a first end to the tank 104 and at a second end to a wall 116. As used herein, the term “wall” used in the context of a spring damper or other energy-absorbing element attached to a wall can refer to the wall of a building or the wall of any other rigid structure to which the spring damper or energy absorber is attached to anchor an immersion cooling system.

The base 112, as well as any other base described or referenced herein (e.g., base 412, 912), can be a floor of the building in which the immersion cooling system 100 is located or other suitable structure, such as a rigid platform secured to a floor. The tank 104 rests on ball bearings 128 positioned between the tank 104 and the base 112. The ball bearings 128 allow for movement of the tank 104 relative to the base 112, which can reduce tank damage and cooling liquid spillage during a seismic event, as already discussed. In some embodiments, the ball bearings 128 can be part of a ball transfer plate or other suitable structure that holds the ball bearings 128 in place.

The spring damper 108 is illustrated in FIG. 1 by a spring damper model that comprises a spring element 120 and a damper element 124. The spring element 120 provides an opposing force to the tank 104 pushing against or pulling away from the spring element 120 and absorbs the kinetic energy caused by movement of the immersion tank 104 during a seismic event. The damper element 124 dampens the movement of the tank 104 by providing resistance to the tank movement and dissipates the energy absorbed by the spring element 120 into the environment as heat. In some embodiments, the spring element 120 can be a coil spring or other suitable type of spring and can comprise metal, rubber, polyurethane, or other suitable elastomeric material. Although the spring damper 108 is illustrated as having separate spring and damper elements, the spring damper 108 may not comprise separate spring and damper components. For example, the spring damper 108 can be a hydraulic shock absorber that comprises a piston moving through a fluid-filled chamber. The resistance provided by the fluid to the moving piston can act as both a damper (the friction provided by the fluid generating heat to dissipate the kinetic energy of the moving tank) and a spring (the resistance of the fluid and the compression of fluid providing an opposing force to the moving tank).

Any spring damper described herein can comprise any suitable damper, such as a hydraulic damper (e.g., mono-tube hydraulic damper, twin-tube hydraulic damper), a gas-charged damper (e.g., gas-pressurized damper, mono-tube gas dampers), an electromagnetic damper, or a friction damper. Dampers whose damping properties can be adjusted dynamically, such as electronically controllable dampers (e.g., electromagnetic dampers), can be used in immersion cooling systems that provide an active response to a seismic event, as will be discussed in greater detail below.

In some embodiments, other types of energy absorbers can be used in place of the spring damper 108 or any other spring damper described herein. Other types of energy absorbers that can be used in an immersion cooling system to absorb the kinetic energy of an immersion tank include viscous liquid dashpots, viscous gas dashpots, rubber or other polymer materials, or any other suitable material or device. In any of the embodiments described herein, the cooling liquid can be mineral oil or other suitable dielectric liquid.

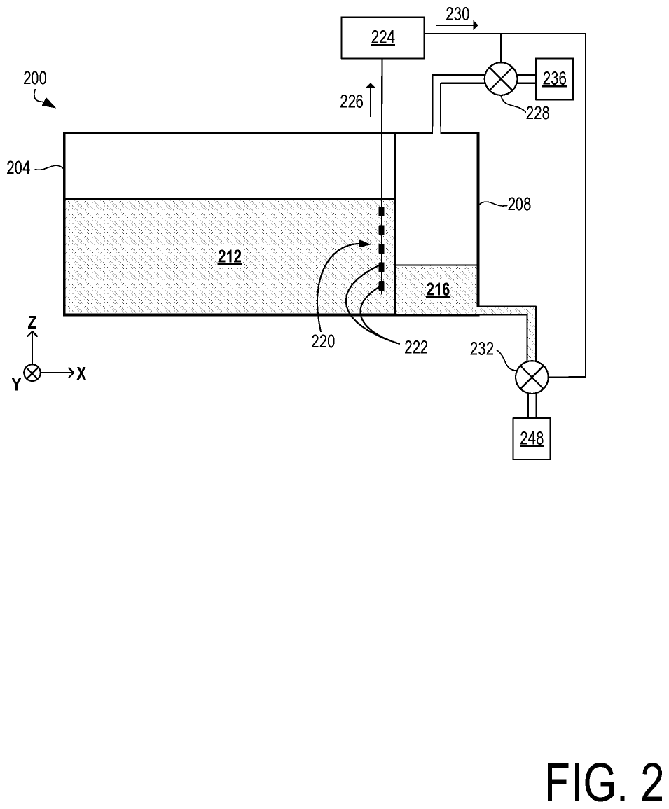

FIG. 2 is a block diagram of a second example immersion cooling system comprising components to mitigate the effects of seismic events on immersion cooling systems. The immersion cooling system 200 comprises an immersion tank 204 and a compensation tank 208. The immersion tank 204 contains cooling liquid 212 and the compensation tank contains liquid 216. The immersion cooling system 200 further comprises a sensor 220, a controller 224, a controllable inlet valve 228, and a controllable outlet valve 232. The sum of the masses of the cooling liquids 212 and liquid 216 is kept substantially constant during a seismic event through the addition or removal of liquid 216 to the compensation tank 208 in response to the immersion tank 204 losing or gaining cooling liquid 212, respectively. By maintaining a constant immersion cooling system mass, the immersion cooling system can provide a consistent response to seismic events. This can be advantageous where, for example, the immersion cooling system has been tuned to provide a desired response to typical seismic events experienced in the geographic area where the immersion cooling system resides. For example, the total mass of the liquids in the immersion tank 204 and the compensation tank 208 can be selected such that the resonant frequency of the immersion cooling system 200 is sufficiently offset from frequencies where earthquakes common to the region release most of their energy.

The sensor 220 provides sensor data 226 to the controller 224 indicating a level of the cooling liquid 212 in the tank 204. The sensor 220 illustrated in FIG. 2 comprises five constituent sensors 222 that each provide sensor data indicating the presence or absence of the cooling liquid 212 at the level of the individual sensor 222. In other embodiments, the sensor 220 can comprise other suitable sensors that can measure the level of a liquid, such as a magnetic float switch, an ultrasonic level sensor, a capacitive level sensor, or an optical level sensor.

The controller 224 receives the sensor data 226 from the sensor 220 and determines whether there has been a change in the level of the cooling liquid. In some embodiments, the controller 224 can determine a change in the cooling liquid level by comparing a cooling liquid level based on current sensor data 226 to a cooling liquid based on prior sensor data 226. If the controller 224 determines that the level of the cooling liquid has changed, by, for example, determining that a current cooling liquid level has changed from a prior cooling liquid level by more than a threshold amount, the controller 224 can generate control signals 230 that are transmitted to the controllable inlet valve 228 and/or the controllable outlet valve 232 to cause liquid to be added to or removed from the compensation tank 208, respectively. The controllable inlet valve 228 can cause liquid to be added to the compensation tank 208 by allowing liquid from a source 236 to flow into the compensation tank and the controllable outlet valve 232 can cause liquid 216 to be removed from the compensation tank 208 by allowing liquid from the compensation tank 208 to flow through conduits to a sink 248. Although FIG. 2 illustrates a controllable inlet valve that is separate from a controllable outlet valve, in other embodiments, a single component (e.g., a controllable inlet/outlet valve) can allow fluid to be added to or removed from the compensation tank 208.

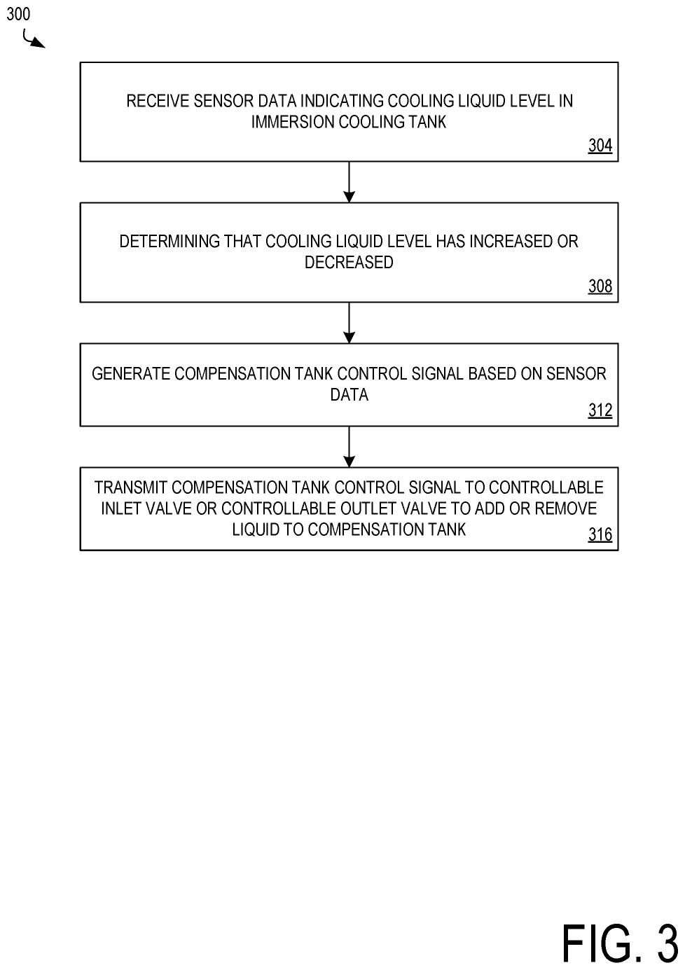

FIG. 3 is an example method of maintaining a constant mass of liquid in an immersion cooling system. At 304 in the method 300, sensor data is received from one or more sensors, the sensor data indicating a cooling liquid level in an immersion tank. At 308, it is determined that the cooling liquid level has increased or decreased based on the sensor data. At 312, a compensation tank control signal is generated based on the sensor data. At 316, the compensation tank control signal is transmitted to a controllable inlet valve and/or a controllable outlet valve, the controllable inlet valve to control the addition of liquid to a compensation tank attached to the immersion tank based on the compensation tank control signal, the controllable outlet valve to control the removal of liquid from the compensation tank based on the compensation tank control signal.

In other embodiments, the method 300 can comprise one or more additional elements or other limitations. For example, determining that the cooling liquid level has increased or decreased comprises determining that the cooling liquid level has increased or decreased by more than a threshold amount from a prior cooling liquid level. In another example, the method 300 can further comprise receiving the compensation tank control signal at the controllable inlet valve and causing liquid to be added to the compensation tank based on the compensation tank control signal.

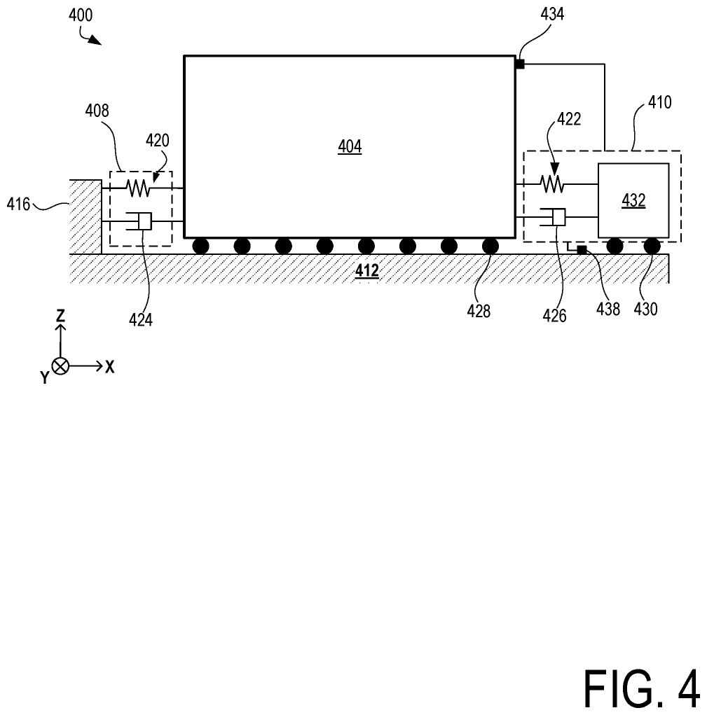

FIG. 4 is a block diagram of a third example immersion cooling system comprising components to mitigate the effects of seismic events on immersion cooling systems. The immersion cooling system 400 comprises an immersion tank 404, spring damper 408, and a tunable mass damper system 410. The immersion tank 404 is located on a base 412. The tank 404 rests on ball bearings 428 positioned between the tank 404 and the base 412 and a tunable mass 432 of the tunable mass damper system 410 rests on ball bearings 430 positioned between the tunable mass 432 and the base 412. The ball bearings 430 allow for movement of the tunable mass 432 relative to the base 412, which can mitigate the effects of seismic events on the tunable mass 432.

Spring damper 408 is attached at a first end to the tank 404 and at a second end to a wall 416 and comprises a spring element 420 and a damper element 424. The spring damper 408 can be any of the spring dampers described or referenced herein. The tunable mass damper system 410 comprises a spring element 422, a damper element 426, and the tunable mass 432. The spring element 422 can be any spring described or referenced herein, the damper element 426 can be any damper described or referenced herein, and the tunable mass 432 is a component that can have its mass adjusted in response to control signals (tunable mass control signals) received at the tunable mass.

As such, the tunable mass damper system 410 can allow the immersion cooling system 400 to provide an active response to a seismic event. The mass of the tunable mass 432 can be tuned based on sensor data provided by an accelerometer 434 attached to the tank 404 and/or an accelerometer 438 attached to or located in the base 412. The accelerometers 434 and 438 generate sensor data indicating movement of the tank and the base, respectively, in one or more directions. The sensor data is provided to a controller (not illustrated in FIG. 4) that can be part of the tunable mass damper system 410 or immersion cooling system 400 or located remotely from the immersion cooling system 400. For example, accelerometers 434 and 438 can provide sensor data to a remote controller that generates control signals for a plurality of immersion cooling systems, such as all of the immersion cooling systems located in the same building or on the same floor in the same building. The controller generates one or more tunable mass control signals that cause the mass of the tunable mass 432 to be adjusted based on a seismic event that the immersion cooling system 400 is being subjected to. The accelerometers 434 and 438 can provide sensor data to the controller via wired or wireless connections, or a combination thereof.

In some embodiments, the tunable mass 432 can comprise a reservoir to which liquid is added or removed in response to the occurrence of a seismic event. The tunable mass 432 can comprise a controllable inlet vale that causes liquid to be added to the tunable mass 432 and a controllable outlet valve that causes liquid to be removed from the tunable mass 432. In some embodiments, a single controllable component controls the addition and removal of liquid to the reservoir.

In some embodiments, characteristics of the spring element 422 and/or the damper element 426 can be adjusted in response to the occurrence of a seismic event. For example, in some embodiments, the tunable mass damper system 410 comprises a damper with controllable damping properties, such as an electromagnetic damper. In an electromagnetic damper, the amount of current flowing through an electromagnet in the damper changes the strength of the magnetic field generated by the electromagnet and thus, the damping force experienced by the moving part of the damper (e.g., a piston), which is made of ferrous material or attached to a ferrous component. In other embodiments, the tunable mass damper system 410 comprises another type of controllable damper, such as a hydraulic damper in which the flow of hydraulic fluid in the damper is controllable (e.g., via solenoids) or pneumatic dampers in which the flow of pressured gas can be controlled. In some embodiments, a controllable damping property can be realized by using a fluid in a damper whose viscosity is adjustable, such as a magnetorheological or electrorheological fluid (a fluid whose viscosity changes when subjected to a magnetic field or an electric field, respectively).

In other examples, the tunable mass damper system 410 comprises a spring with controllable spring properties, such as an electromagnetic spring (e.g., a spring comprising ferrous material located between coaxial magnets, the stiffness of the electromagnetic spring being adjustable by varying the amount of current flowing through the spring or by varying the strength of the magnets).

In some embodiments, multiple spring dampers are placed in parallel and the spring and the damping properties of a group of parallel spring dampers can be controlled by enabling or disabling one or more spring dampers in the group of parallel spring dampers. For example, in some embodiments, disabling a spring damper can comprise causing the spring and damping properties of the spring damper to provide zero or a low amount of offsetting spring force to a moving immersion tank relative to the other spring dampers in the group or zero or a low amount of damping relative to the other spring dampers.

Whether a tunable mass damper system has only a mass that is tunable or a mass and a spring damper that are tunable, the controller determines the control signals to adjust the tunable mass (tunable mass control signals) and/or the tunable spring damper (spring damper control signals) to reduce the amount of tank movement in the immersion cooling system. These control signals can be determined based on sensor data provided by the accelerometer attached to the tank, by the accelerometer attached to the base, or both. In some embodiments, the controller can determine a desired transfer function for the immersion cooling system (a desired physical response of the immersion cooling system to a seismic event) and determine adjustments to be made to the tunable components of the immersion cooling system based on the transfer function. The controller can then determine the control signals to be sent to the tunable immersion cooling system components and transmit those control signals to those components. In other embodiments, the controller can analyze accelerometer sensor data during a seismic event to determine if the seismic event comprises a frequency component that matches one or more resonant frequencies of the immersion cooling system and determine adjustments to be made to the tunable elements of the immersion cooling system to dampen a resonant response of the immersion cooling system.

In some embodiments, the controller can employ a feedback loop. For example, after determining the occurrence of a seismic event and causing an initial adjustment to tunable mass damper system components (e.g., tunable mass, tunable spring damper) to be made, the controller can continue to adjust properties of tunable mass damper system components in real-time (strong earthquakes can last as long as several minutes) based on accelerometer sensor data that is continued to be received during the seismic event.

In some embodiments, a controller can receive sensor data from an accelerometer and determine spring damper control signals to cause an adjustment to a spring property and/or a damping property of a spring damper that is not part of a tunable mass damper system, such as spring dampers 108, 408, and 1036.

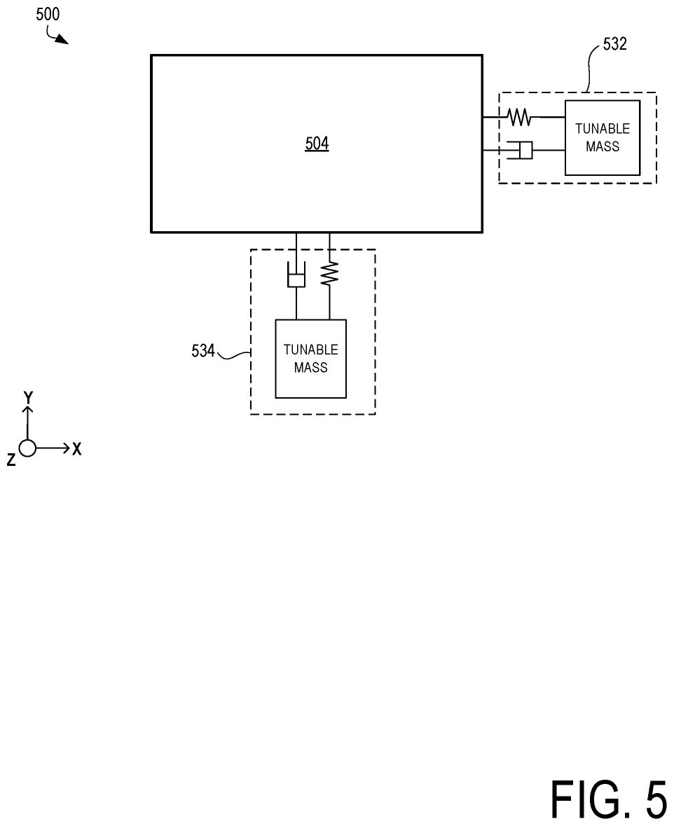

FIG. 5 is a block diagram of a top view of a fourth example immersion cooling system comprising components to mitigate the effects of seismic events on immersion cooling systems. While FIG. 4 illustrates the presence of a tunable mass damper system 410 arranged to dampen motion of the tank 404 in just the x-direction, FIG. 5 illustrates an immersion cooling system 500 comprising a tunable mass damper system 532 arranged substantially orthogonally to a tunable mass damper system 534, the tunable mass damper systems arranged to dampen motion of an immersion tank 504 in the x-direction (tunable mass damper system 532) and the y-direction (tunable mass damper system 534). Each of the tunable mass damper systems 532 and 534 can be controlled by a controller dedicated to controlling one of the systems, or the tunable mass damper systems 532 and 534 can be collectively controlled by a single controller. The use of tunable mass damper systems to limit the motion of an immersion tank is not limited to just one or two dimensions. In some embodiments, multiple tunable mass damper systems can be arranged to limit motion of an immersion tank in x, y, and z-dimensions to provide a three-dimensional damping solution. Any other immersion cooling system element or component disclosed herein, such as spring dampers and crumple blocks, that acts as an energy absorber can also be used to implement one-, two-, or three-dimensional damping solutions. For example, an immersion cooling system can comprise three spring dampers that are oriented substantially orthogonal to each other. An energy absorbing element oriented in the z-direction can be attached to the base or a structure located above the immersion tank.

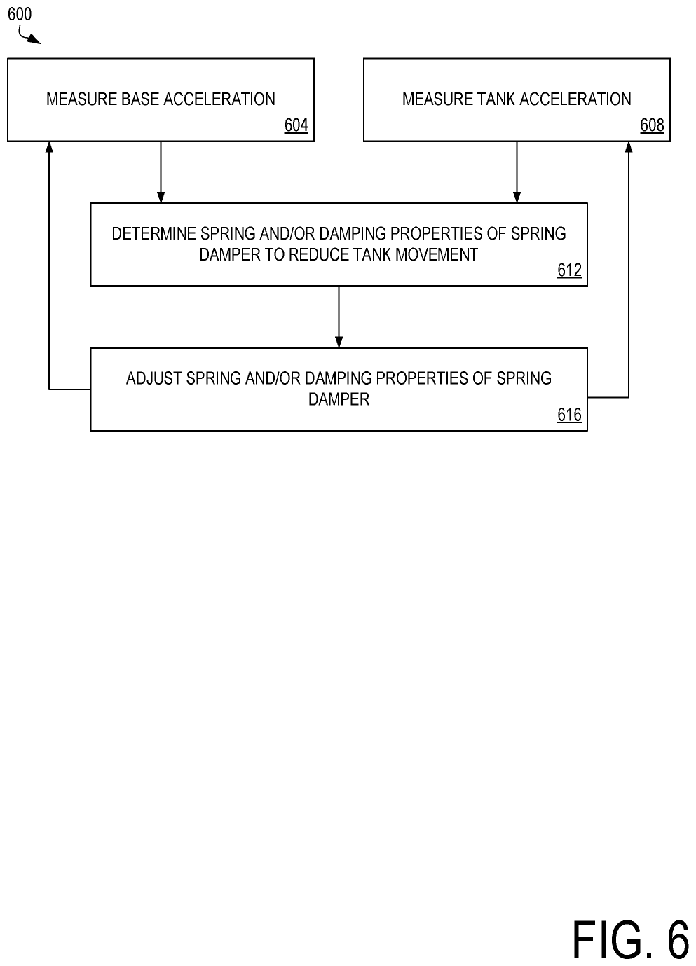

FIG. 6 is a first example method of mitigating the effects of seismic events on immersion cooling systems. The method 600 mitigates the effect of a seismic event on an immersion cooling system by adjusting one or more properties of a spring damper. At 604, acceleration of a base that an immersion tank is located on is measured by an accelerometer attached to or located in the base. At 608, immersion tank acceleration is measured. Immersion tank acceleration can be measured by an accelerometer attached to the immersion tank. At 612, spring and/or damping properties of a spring damper to reduce tank movement are determined. Based on the acceleration measurements, in some embodiments, only spring properties or only damping properties of a spring damper may be determined. In some embodiments where an immersion cooling system comprises multiple spring dampers, spring and/or damping properties of multiple spring dampers can be determined at 612. At 616, spring and/or damping properties of a spring damper are adjusted. The method 600 then returns to 604 and 608 to continue to measure base and immersion tank acceleration.

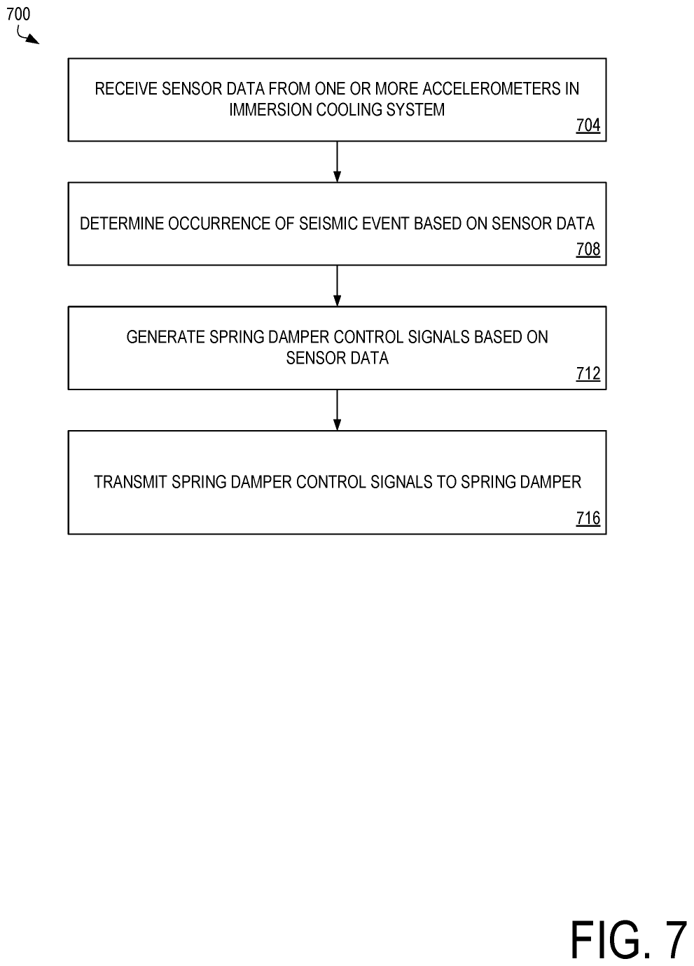

FIG. 7 is a second example method of mitigating the effects of seismic events on immersion cooling systems. The method 700 mitigates the effect of a seismic event on an immersion cooling system by adjusting one or more properties of the spring damper. At 704, sensor data is received from one or more accelerometers in an immersion cooling system, the immersion cooling system comprising an immersion tank and a spring damper, a first end of the spring damper attached to the immersion tank, a second end of the spring damper attached to a wall or a base, the immersion tank located on the base. At 708, the occurrence of a seismic event based on the sensor data is determined. At 712, one or more spring damper control signals are generated based on the sensor data. At 716, the one or more spring damper control signals are transmitted to the spring damper, the spring damper control signals to cause an adjustment to a spring property and/or a damping property of the spring damper.

In other embodiments, the method 700 can comprise one or more additional elements or other limitations. For example, method 700 can further comprise determining a magnitude of the seismic event in response to determining the occurrence of the seismic event, wherein generating the one or more spring damper control signals and transmitting the one or more control signals to the spring damper are performed in response to determining that the magnitude of the seismic event exceeds the seismic event magnitude threshold. The seismic event magnitude threshold can be any value, such as a value of 5.0 on the Richter scale.

In another example of method 700, the spring damper is a first spring damper, the one or more spring damper control signals are first one or more spring damper control signals, and the wall is a first wall, wherein the first end of the first spring damper is attached to a first wall of the immersion tank and the second end of the first spring damper is attached to the first wall or the base, the immersion cooling system further comprises a second spring damper, a first end of the second spring damper attached to a second wall of the immersion tank that is substantially orthogonal to the first wall or the immersion tank, a second end of the second spring damper attached to the first wall, the second wall, or the base, the method 700 further comprising:

generating one or more second spring damper control signals based on the sensor data; and transmitting the one or more second spring damper control signals to the second spring damper, the second spring damper control signals to cause a change to a spring property and/or a damping property of the second spring damper.

In yet another example of method 700, the immersion cooling system further comprises a third spring damper, a first end of the second spring damper attached to the immersion tank, the third spring damper oriented substantially orthogonal to the first spring damper and the spring damper, a second end of the second spring damper attached to the base or a structure located above the immersion tank, the method 700 further comprising: generating one or more second spring damper control signals based on the sensor data; and transmitting the one or more second spring damper control signals to the second spring damper, the second spring damper control signals to cause change to a spring property and/or a damping property of the second spring damper.

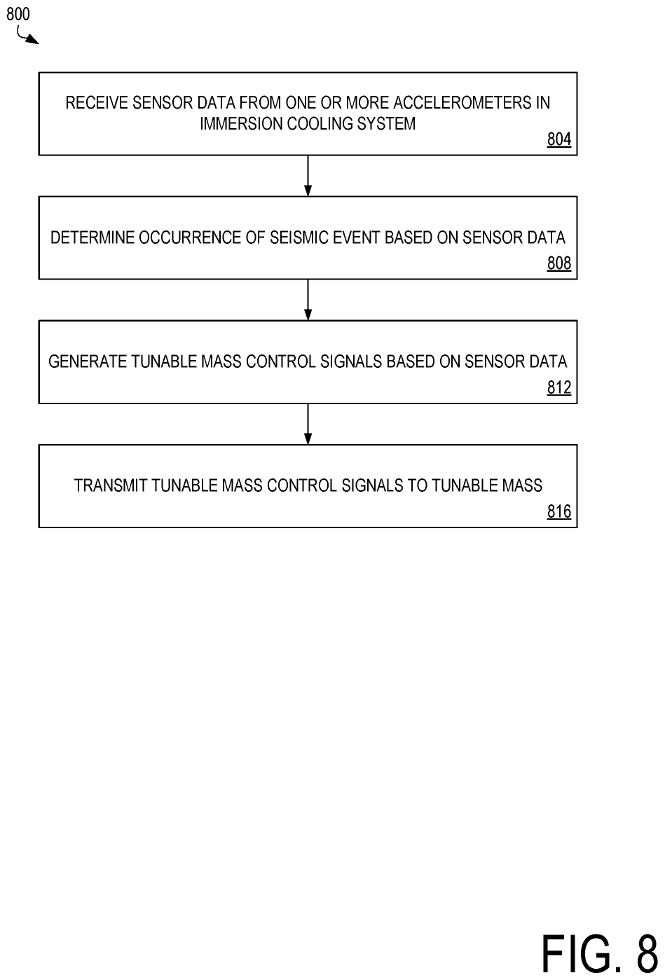

FIG. 8 is a third example method of mitigating the effects of seismic events on immersion cooling systems. The method 800 mitigates the effect of a seismic event of an immersion cooling system by adjusting a tunable mass. At 804 in method 800, sensor data is received from one or more accelerometers in an immersion cooling system, the immersion cooling system comprising an immersion tank, a tunable mass, a spring damper, a first end of the spring damper attached to the immersion tank, a second end of the spring damper attached the tunable mass. At 808, the occurrence of a seismic event based on the sensor data is determined. At 812, one or more tunable mass control signals are generated based on the sensor data. At 816, the one or more tunable mass control signals are transmitted to the tunable mass, the tunable mass control signals to cause a change to a mass of the tunable mass.

In other embodiments, the method 800 can comprise one or more additional elements or other limitations. For example, method 800 further comprises determining whether a magnitude of the seismic event is greater than a seismic event magnitude threshold, wherein generating the one or more tunable mass control signals and transmitting the one or more tunable mass control signals to the reservoir are performed if the magnitude of the seismic event exceeds the seismic event magnitude threshold. In another example of method 800, the tunable mass is a first tunable mass, the spring damper is a first spring damper, the one or more tunable mass control signals are one or more first tunable mass control signals, the immersion cooling system further comprising a second tunable mass and a second spring damper, a first end of the second spring damper attached to the immersion tank, the first spring damper substantially orthogonal to the second spring damper, the method further comprising: generating one or more second tunable mass control signals based on the sensor data; and transmitting the one or more second tunable mass control signals to the second tunable mass, the second tunable mass control signals to cause a change to the mass of the second tunable mass. In yet another example of method 800, the immersion cooling system further comprises a third tunable mass and a third spring damper, a first end of the third spring damper attached to the immersion tank and a second end of the third spring damper attached to the base or a structure located above the immersion tank, the third spring damper oriented substantially orthogonal to the first spring damper and the second spring damper, the method further comprising: generating one or more third tunable mass control signals based on the sensor data; and transmitting the one or more third tunable mass control signals to the third tunable mass, the third tunable mass control signals to cause a change to the mass of the third tunable mass.

FIG. 9 is a block diagram of a fifth example immersion cooling system comprising components to mitigate the effects of seismic events on immersion cooling systems. The immersion cooling system 900 comprises an immersion tank 904, spring dampers 908 and 910, and a crumple block 928. The immersion tank 904 is located on a base 912. The spring damper 908 is attached at a first end of the spring damper 908 to the tank 904 by a bracket 936 and at a second end of the spring damper 908 to the base 912 by a bracket 940. The bracket 936 is secured to the tank 904 by screws 944 and the bracket 940 is secured to the base 912 by a screw 948. The spring damper 910 is mounted at a first end of the spring damper 910 to the tank 904 by a plate 952 and a second end of the spring damper 910 is attached to the base by a bracket 956. The plate 952 is mounted to the tank 904 through preloading of the spring of the spring damper. That is, the plate 952 is mounted to the tank 904 by the spring damper 910 pushing the plate 952 against tank 904 in the absence of a seismic event. The bracket 956 is attached to the base 912 by screws 960.

Mounting of the spring damper 910 to the tank 904 via spring preloading can provide for greater vibration and shock resistant than attachment of a spring damper to the tank 904 by screws (e.g., screws 944). During a seismic event, the screws 944 may suffer damage due to movement of the tank, which could lead to cooling liquid leakage, damage to the tank, or other undesirable outcomes. Further, the use of spring-preloaded mounts provides flexibility in selecting a mount location. This can be beneficial as desirable locations to place a spring damper mount can vary depending on tank design, characteristics of the base, and other conditions.

The crumple block 928 is attached at one end of the crumple block 928 to the tank 904 and at a second end of the crumple block 928 to a wall 916. The crumple block 928 is an energy-absorbing component designed to crumple or deform under the load of the tank 904 moving during a seismic event. The crumple block 928 can be a structure that lends itself to collapsing under expected tank movement loads during a seismic event. In some embodiments, the crumple block 928 can comprise a structure comprising foam, a crushable metal, plastic, or other suitable material. In some embodiments, the crumple block can have a honeycomb structure. In other embodiments, the crumple block can be a gel-filled accordion-like structure to absorb immersion tank kinetic energy. As the crumple block 928 can be crumpled or deformed during a seismic event, the crumple block can be replaceable.

A frictional layer 964 of material is positioned between the tank 904 and the base 912. The frictional layer 964 allows for smooth movement of the tank 904 (that is, without sticking) relative to the base 912 while providing friction to dampen tank movement. The frictional layer 964 absorbs the kinetic energy of the tank 904 through frictional heat and can dampen the tank movement quickly. The frictional layer 964 can comprise silt, sand, gravel, a sand-like material, or other suitable material. The frictional coefficient of the frictional layer 964 can be selected through the selection of the frictional layer material, such as the type of sand and sand grain size. In other embodiments, ball bearings could be used in the immersion cooling system 900 in place of a frictional layer. Further, a frictional layer could be used in place of ball bearings in the immersion cooling systems illustrated in FIGS. 1, 2, 4, and 5.

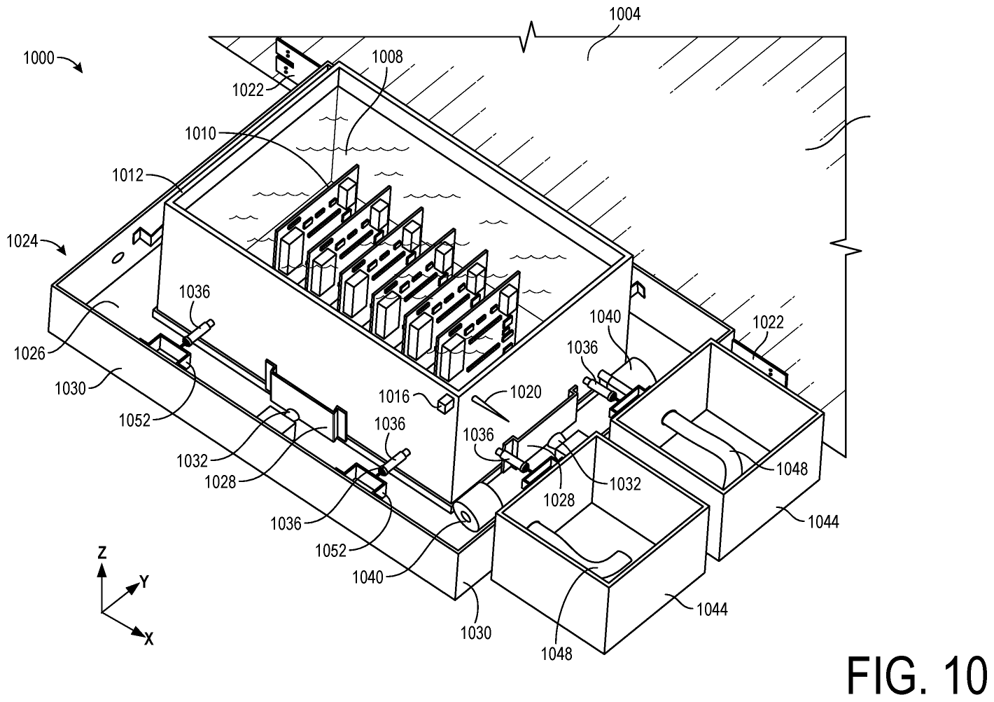

FIGS. 10-13 illustrate various views of a sixth example immersion cooling system comprising components to mitigate the effects of seismic events on immersion cooling systems. FIG. 10 is a perspective view of an immersion cooling system 1000 comprising an immersion tank 1012, a housing pallet 1024, spring dampers 1036, shutoff switches 1032, and secondary reservoirs 1044. The immersion tank 1012 is located within the housing pallet 1024 and the secondary reservoirs 1044 are located outside of the housing pallet 1024. The housing pallet 1024 comprises a bed 1026 and walls 1030. The immersion tank 1012 is located within the walls 1030. The housing pallet 1024 is attached to a wall 1004 by brackets 1022. The brackets 1022 can be made of steel or another suitable material and be brazed to the wall in accordance with appropriate standards (e.g., IBC, ASCE standards). The walls 1030 of the housing pallet 1024 restrict movement of the tank to a confined area and can contain cooling liquid spills. The housing pallet 1024 illustrated in FIGS. 10-13 is rectangular and has four walls with a pair of spring dampers and a shutoff switch attached to each wall. The spring dampers oriented in the x-direction are substantially orthogonal to the spring dampers oriented in the y-direction. In other embodiments, the housing pallet can take on other shapes, and all or fewer than all walls can have a spring damper and a shutoff switch attached to them.

In some embodiments, the housing pallet 1024 can comprise one or more leak sensors that provide sensor data indicating a leak to a controller. In some embodiments, a leak sensor can comprise information indicating an immersion cooling system identifier and/or information indication the location of the immersion cooling system within a data center or other facility. Upon receipt of information indicating a leak, the controller can take appropriate action, such as shutting down power to components in the immersion cooling system experiencing the leak, transferring cooling liquid from the tank to secondary reservoirs (as will be discussed below), or otherwise causing the immersion cooling system to enter a safe state. The controller can further alert facility personnel to the presence of a leak.

During a seismic event, the tank 1012 is able to move within the pallet while the pallet remains arrested to the wall 1004. That tank is able to move within the housing pallet 1024 in that it can move in the x- and y-directions, as well as rotationally about the z-axis. In some embodiments, movement of the tank within the pallet is enabled by ball bearings positioned between the tank and the housing pallet. The ball bearings can be part of a ball transfer plate. In some embodiments, the ball transfer plate is made of zinc-plated steel and the balls are made of corrosion-resistant steel with a dynamic load rating. In one example of a ball transfer plate, the plate can comprise 24 balls that can each handle 65 lbs., totaling 1560 lbs. for the ball transfer plate. More or fewer balls can be used to adjust the load capacity of the ball transfer plate in other embodiments. The individual spring dampers 1036 are attached at a first end to the tank 1012 and at a second end to one of the walls 1030 via brackets 1052. In some embodiments, the spring dampers 1036 can be attached directly to the walls 1030 of the housing pallet 1024. The spring damper 1036 can be any of the spring dampers 1036 described herein. The spring dampers 1036 can be calibrated such that any of the shutoff switches are activated by the immersion tank 1012 when the immersion cooling system experiences a seismic event exceeding a predetermined (or user-specified) seismic magnitude threshold (e.g., a Richter scale value of 5.0).

Printed circuit boards 1010 are located in the tank 1012 and are immersed in cooling liquid 1008. In some embodiments, printed circuit boards can be partially immersed in cooling liquid 1008. For example, one or more integrated circuit components attached to a printed circuit board that generate less heat than other integrated circuit components attached to the printed circuit board may not be immersed in the cooling liquid 1008.

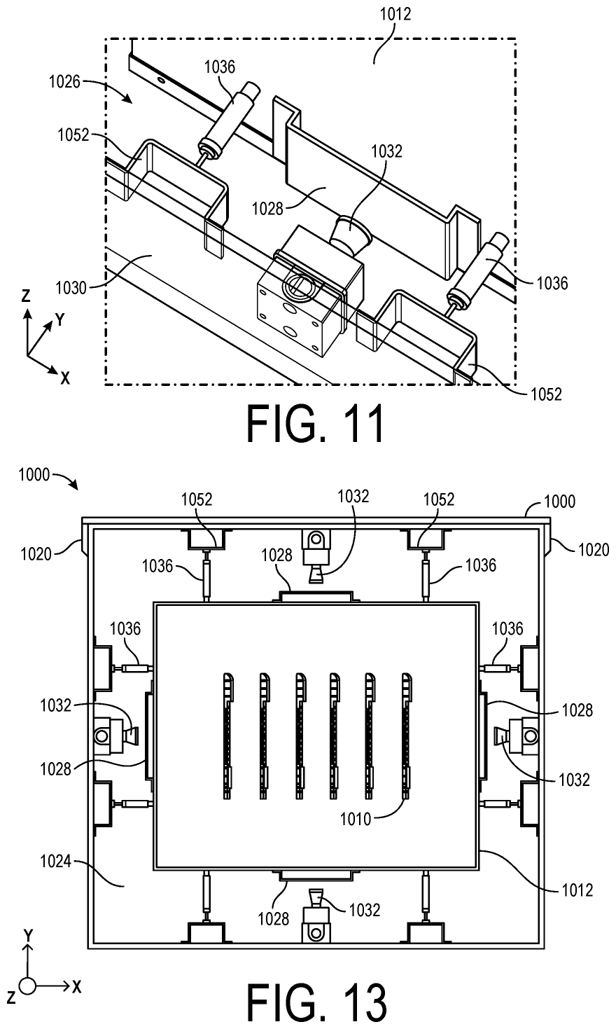

FIG. 11 is a close-up view 1100 showing a more detailed view of a shutoff switch 1032, a pusher plate 1028, and spring damper 1036. Pusher plates 1028 are attached to the tank 1012, with each pusher plate 1028 spaced from one of the shutoff switches 1032 in the absence of a seismic event. Each pusher plate 1028 is further able to activate an associated shutoff switch 1032 due to the tank crossing the distance between a pusher plate and its associated shutoff switch during a seismic event. The shutoff switches 1032 can be push button switches or any other suitable switch and the pusher plate 1028 can comprise metal or any other sufficiently rigid material that can activate a shutoff switch 1032 when the pusher plate 1028 pushes against the shutoff switch 1032. The distance from a pusher plate 1028 to an associated shutoff switch 1032 in the absence of a seismic event can be calibrated for a specific immersion cooling system configuration and desired immersion cooling system response to seismic events. For example, the distance between a pusher plate 1028 and an associated shutoff switch 1032 can be selected based on the magnitude of a seismic event the immersion cooling system 1000 is to endure before it activates the shutoff switch 1032 due to tank movement. Although the pusher plates 1028 are illustrated as U-shaped brackets in FIGS. 10-13, in other embodiments, the pusher plates 1028 can be flat plates secured against the tank 1012, and in still other embodiments, there are no pusher plates, and a wall of the tank 1012 pushes directly against a shutoff switch 1032 to activate the switch.

The shutoff switch 1032 provides switch signal data to a controller (not illustrated in FIGS. 10-13) that causes power to the printed circuit boards 1010 to be shut off when the shutoff switch is activated, placing the immersion cooling system in a safe state. In some embodiments, the controller can cause power for the printed circuit boards 1010 to be turned back on after expiration of a predetermined wait period after the controller has shut off power to the printed circuit boards 1010. In other embodiments, the controller can turn the power back on for the printed circuit boards after determining that a seismic event has ended based on sensor data received from one or more accelerators. Shutting off power to the printed circuit boards 1010 can comprise causing a power supply that provides power to all of the printed circuit boards 1010 to stop delivering power or for one or more power delivery components located on the individual printed circuit boards to stop delivering power to other components attached the printed circuit board. Either way, activation of a shutoff switch 1032 causes power to components attached to the printed circuit boards 1010 to be shut off.

The immersion cooling system 1000 further comprises an accelerometer 1016 and an inertial measurement unit 1020. The inertial measurement unit 1020 comprises an accelerometer and both the inertial measurement unit 1020 and the accelerometer 1016 can provide sensor data indicating acceleration of the tank 1012 in one or more directions (such as in the x-, y-, and/or z-directions). In some embodiments, the inertial measurement unit 1020 can further comprise a gyroscope and sensor data provided by the inertial measurement unit 1020 can comprise information indicating angular velocity of the tank about the x-, y-, and/or z-axes. In some embodiments, an immersion cooling system 1000 comprises either the accelerometer 1016 or the inertial measurement unit 1020, but not both.

In immersion cooling system embodiments comprising an accelerometer and an inertial measurement unit, such as immersion cooling system 1000, at least one of the sensors can provide sensor data wirelessly to a cloud management and orchestration system or other system or service that provides management of the immersion cooling system 1000. The cloud management and orchestration system can provide for the remote monitoring, logging, and control (such as adjustment of immersion cooling system settings (e.g., the seismic event magnitude threshold at which the immersion cooling system is shut off)) of the immersion cooling system 1000 as well as other immersion cooling systems, such as those on the same floor or in the same building as the immersion cooling system 1000.

In some embodiments, either the accelerometer 1016 or the inertial measurement unit 1020 provides their sensor data to a local controller that monitors the sensor data to determine whether the immersion cooling system is to enter a safe state and, if so, causes power to the printed circuit boards 1010 to be shut off and/or causes cooling liquid 1008 to be transferred from the tank 1012 to the secondary reservoirs 1044. In other embodiments, an immersion cooling system comprises either an accelerometer or an inertial measurement unit, and a local or remote controller responsible for managing the immersion cooling system receives the sensor data from the accelerometer or the inertial measurement unit. In some embodiments with a single accelerometer (which could be part of an inertial measurement unit), the accelerometer can provide its sensor data to both a local controller and a remote controller, such as a cloud management and orchestration system, allowing for an immersion cooling system to enter a safe state through either local or remote control.

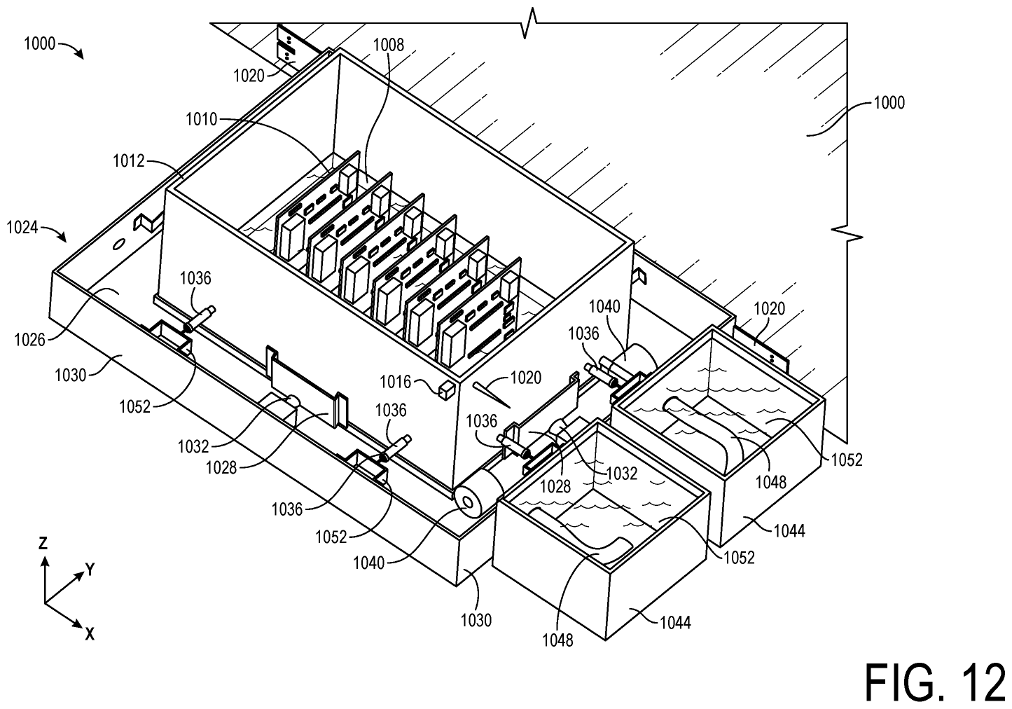

Referring to FIG. 12, which is a perspective view of the immersion cooling system 1000 with a portion of the cooling liquid transferred from the immersion cooling tank 1012 to the secondary reservoirs 1044, the accelerometer 1016 and the inertial measurement unit 1020 can each provide sensor data in a wired or wireless manner to a controller (not illustrated in FIGS. 10-13). The controller causes liquid to be transferred from the immersion tank 1012 to secondary reservoirs 1044 in response to determining the presence of a seismic event based on the sensor data. The controller causes cooling liquid 1008 to be transferred from the tank 1012 to the secondary reservoirs 1044 through control of controllable valves 1040 (which can be manifold valves or other suitable controllable valves). The cooling liquid 1008 can flow between the tank 1012 and the secondary reservoirs 1044 via controllable valves 1040 and conduits 1048. During a seismic event, cooling liquid 1008 can be transferred from the tank 1012 to the secondary reservoirs 1044 to prevent loss of the cooling liquid 1008 due to spilling of the cooling liquid 1008 over the edges of the tank 1012, and to reduce the risk of damage to the printed circuit boards 1010 by reducing the mass of the cooling liquid 1008 sloshing around the tank 1012. In some embodiments, 50% of the cooling liquid 1008 can be transferred from the tank 1012 to the secondary reservoirs 1044 during a seismic event. In other embodiments, other amounts of cooling liquid 1008 can be transferred from the tank to the reservoirs during a seismic event, such as 20% or 80% (or any percentage in between). The secondary reservoirs 1044 are covered (reservoir covers not shown in FIGS. 10 and 13) to prevent the spilling of cooling liquid 1008 while the cooling liquid 1008 is located in the secondary reservoirs 1044.

The controller can determine the presence of a seismic event based on sensor data received from the accelerometer 1016, the inertial measurement unit 1020, or both. In some embodiments, the controller can determine the presence of a seismic event by utilizing a machine learning model that has been trained on accelerometer and/or inertial measurement unit sensor data generated during seismic events. In some embodiments, the trained machine learning model can be trained to identify the beginning stages of a seismic event—before the magnitude of a seismic event reaches the point where the tank begins to move, only starts to move, or has begun moving but has yet to activate a shutoff switch—and the controller can shut off power to the printed circuit boards and/or transfer liquid from the immersion tank 1012 to the secondary reservoirs 1044 if a beginning stage of a seismic event is detected. In this manner, a controller can anticipate a seismic event and take preventive measures to protect the immersion cooling system.

In addition to reducing the amount of cooling liquid 1008 in the tank 1012 to mitigate cooling liquid loss and tank damage, transfer of cooling liquid 1008 to secondary reservoirs 1044 (which are located outside of the housing pallet 1024) adjusts the mass of the immersion tank and alters its natural frequency. In some embodiments, the controller can determine an amount of cooling liquid 1008 to transfer to the secondary reservoirs 1044 that adjusts the natural frequency of the immersion tank 1012 to reduce its response to a seismic event currently in progress. FIGS. 10 and 13 illustrate two secondary reservoirs 1044, but in other embodiments, an immersion cooling system can have more or fewer secondary reservoirs.

The controller can cause cooling liquid to be transferred from the secondary reservoirs 1044 back to the tank 1012 after a predetermined wait period has elapsed after transfer of the cooling liquid to the secondary reservoirs 1044 or after the controller determines that the current seismic event has ended based on sensor data. The controller can cause the cooling liquid 1008 to flow from the secondary reservoirs 1044 to the tank 1012 via the controllable valves 1040. The immersion cooling system 1000 can further comprise a pump (not illustrated in FIGS. 10-13) to assist in the transfer of cooling liquid between the tank 1012 and the secondary reservoirs 1044. In some embodiments, a single controller can cause the transfer of cooling liquid 1008 between the tank 1012 and secondary reservoirs 1044 and the shutting off and turning on of power to the printed circuit boards 1010. In other embodiments, these tasks can be handled by separate controllers. Any controller that manages the mitigation effects of seismic events on the immersion cooling system 1000 can be located local to or remote from the immersion cooling system 1000. A remote controller can receive sensor data from shutoff switches and/or accelerometers from a plurality of immersion cooling systems and can cause printed circuit board power to be shut off or cooling liquid to be transferred from an immersion tank to secondary reservoirs for a plurality of immersion cooling systems.

FIG. 13 is a top view of the immersion cooling system 1000 and illustrates the presence of a pair of spring dampers 1036 and a shutoff switch 1032 attached to each side of a tank. In other embodiments, spring dampers and/or shutoff switches can be located on fewer than all of the sides of an immersion tank.

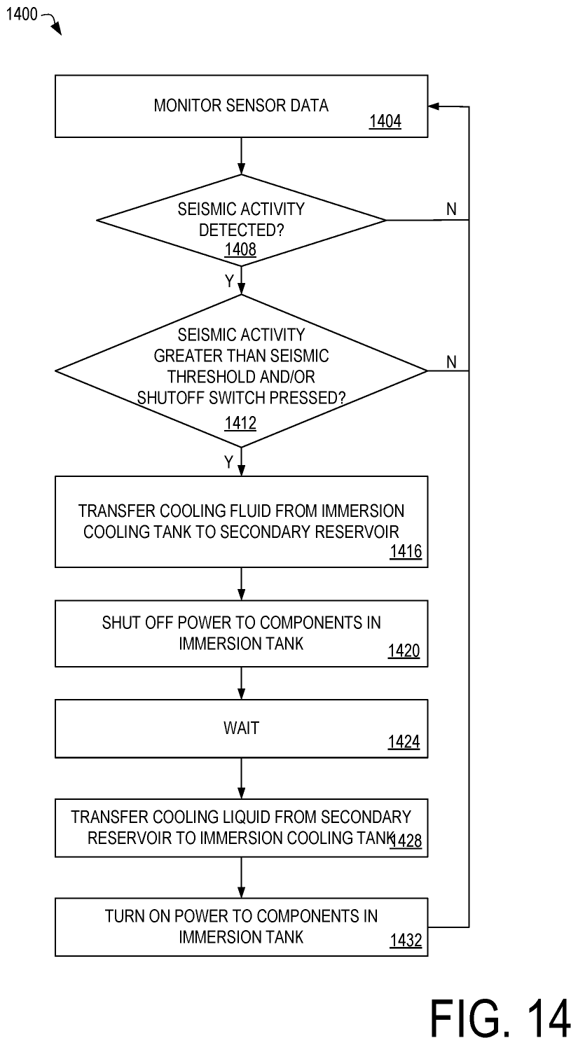

FIG. 14 is a fourth example method of mitigating the effects of seismic events on immersion cooling systems. The method 1400 mitigates the effect of a seismic event of an immersion cooling system by shutting off power to printed circuit boards located in the immersion tank and transferring cooling liquid from the immersion tank to one or more secondary reservoirs. The method 1400 can be performed by a controller local or remote to an immersion cooling system. At 1404, sensor data from an accelerometer and/or inertial measuring unit is monitored. At 1408, seismic activity is detected based on the sensor data. If there is no seismic activity, the senor data continues to be monitored. If seismic activity is detected, at 1412, it is determined whether a magnitude of the seismic activity is greater than a seismic event magnitude threshold and/or whether switch data from a shutoff switch indicates that the shutoff switch has been activated. If the magnitude of the seismic activity is less than the seismic event magnitude threshold and a shutoff switch has not been activated, the sensor data continues to be monitored. At 1416, if the magnitude of the seismic activity is greater than the seismic event magnitude threshold or the switch data indicates that a shutoff switch has been activated, then cooling liquid is transferred from the immersion tank to one or more secondary reservoirs. At 1420, power is shut off to components located in the immersion tanks, such as printed circuit boards or components attached to printed circuit boards. At 1424, the method 1400 waits for a specified time, which can be a predetermined, default, or user-specified time. After expiration of the wait time, cooling liquid is transferred back to the immersion tank at 1428, and power to the components in the immersion tank is restored at 1432.

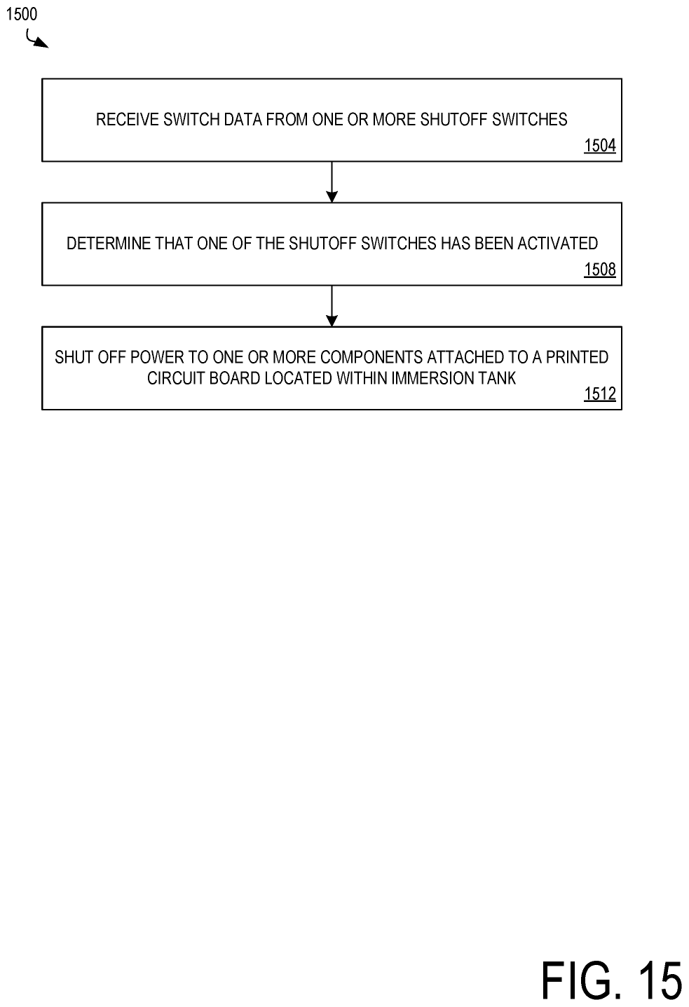

FIG. 15 is a fifth example method of mitigating the effects of seismic events on an immersion cooling system. The method 1500 can be performed by a controller local or remote to an immersion cooling system. At 1504, switch data is received from one or more shutoff switches attached to a housing pallet, the housing pallet housing an immersion tank, the immersion tank able to activate the one or more shutoff switches via movement of the immersion tank within the housing pallet. At 1508, it is determined that one of the one or more shutoff switches has been activated. At 1512, power to one or more components attached to a printed circuit board located within the immersion tank is shut off in response to determining that one of the one or more shutoff switches has been activated.

In other embodiments, the method 1500 can comprise one or more additional elements or other limitations. For example, method 1500 can further comprise, after shutting off power to the one or more components, causing power for the one or more components to be turned on after a predetermined period. In another example, the method 1500 can further comprise causing cooling liquid to transfer from the immersion tank to a reservoir in response to determining that one of the one or more shutoff switches has been activated, the reservoir located outside of the housing pallet. In yet another example, the method 1500 can further comprise, after causing cooling liquid to be transferred from the immersion tank to the reservoir, causing cooling liquid to transfer from the reservoir to the immersion tank after a predetermined period.

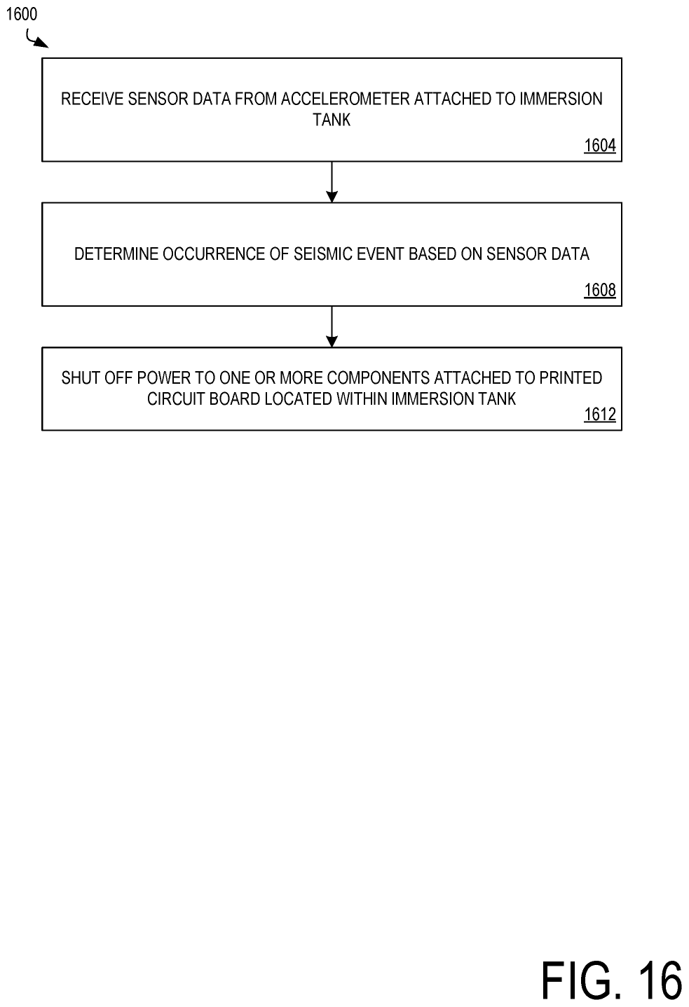

FIG. 16 is a sixth example method of mitigating the effects of seismic events on an immersion cooling system. The method 1600 can be performed by a controller local or remote to an immersion cooling system. At 1604, sensor data is received from an accelerometer attached to an immersion tank. At 1608, the occurrence of a seismic event is determined based on the sensor data. At 1612, power is shut off to one or more components attached to a printed circuit board, the printed circuit board located within the immersion tank.

In other embodiments, the method 1600 can comprise one or more additional elements or other limitations. For example, method 1600 can further comprise, after shutting off power to the one or more components, causing power for the one or more components to be turned on after a predetermined period. In another example, the method 1600 can further comprise determining that a magnitude of the seismic event exceeds a seismic event magnitude threshold, wherein shutting off power to the one or more components occurs in response to determining that the magnitude of the seismic event exceeds the seismic event magnitude threshold. In yet another example, the method 1600 can further comprise causing cooling liquid to transfer from the immersion tank to a reservoir in response to determining the occurrence of a seismic event, wherein the immersion tank is located within a housing pallet and the reservoir is located outside of the housing pallet. In another example, the method 1600 can further comprise after causing cooling liquid to be transferred from the immersion tank to the reservoir causing, causing cooling liquid to be transferred from the reservoir to the immersion tank after a predetermined period. In still another example, the method 1600 can further comprise, after causing cooling liquid to be transferred from the immersion tank to the reservoir, causing power to be turned on for the one or more components after the predetermined period.

In any of the embodiments disclosed herein where a seismic event is to exceed a seismic event magnitude threshold before mitigating actions are taken in an immersion cooling system, the seismic event magnitude threshold can be user-configured, thereby allowing for the components in an immersion cooling system to continue operating until a specified seismic intensity is reached.

The technologies described herein can be performed in whole or in part by or implemented in whole or in part in any of a variety of computing systems or computing devices, including mobile computing systems (e.g., smartphones, handheld computers, tablet computers, laptop computers) and non-mobile computing systems (e.g., desktop computers, servers, workstations, rack-level computing solutions (e.g., blade, tray, or sled computing systems)), or embedded devices (e.g., embedded controllers, such as controllers embedded in an immersion cooling system, tunable mass, spring damper, or tunable mass damper system). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a co-located data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

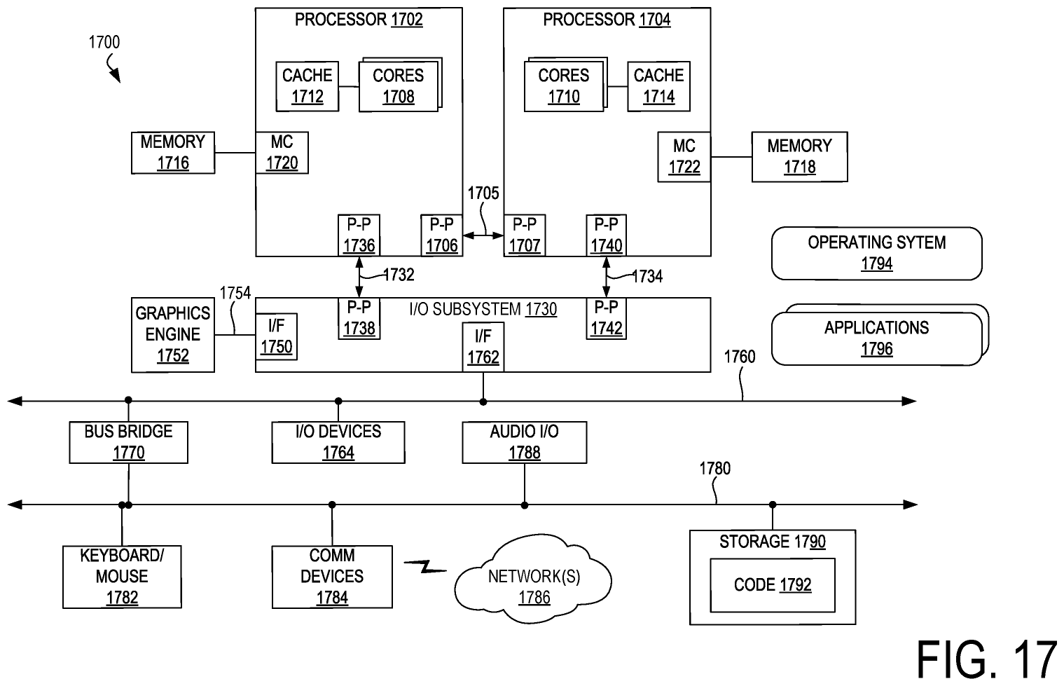

FIG. 17 is a block diagram of an example computing system or computing device in which technologies described herein may be implemented. Generally, components shown in FIG. 17 can communicate with other shown components, although not all connections are shown, for ease of illustration. The computing system 1700 is a multiprocessor system comprising a first processor unit 1702 and a second processor unit 1704 comprising point-to-point (P-P) interconnects. A point-to-point (P-P) interface 1706 of the processor unit 1702 is coupled to a point-to-point interface 1707 of the processor unit 1704 via a point-to-point interconnection 1705. It is to be understood that any or all of the point-to-point interconnects illustrated in FIG. 17 can be alternatively implemented as a multi-drop bus, and that any or all buses illustrated in FIG. 17 could be replaced by point-to-point interconnects.

The processor units 1702 and 1704 comprise multiple processor cores. Processor unit 1702 comprises processor cores 1708 and processor unit 1704 comprises processor cores 1710. Processor cores 1708 and 1710 can execute computer-executable instructions in a manner similar to that discussed below in connection with FIG. 8, or other manners.

Processor units 1702 and 1704 further comprise cache memories 1712 and 1714, respectively. The cache memories 1712 and 1714 can store data (e.g., instructions) utilized by one or more components of the processor units 1702 and 1704, such as the processor cores 1708 and 1710. The cache memories 1712 and 1714 can be part of a memory hierarchy for the computing system 1700. For example, the cache memories 1712 can locally store data that is also stored in a memory 1716 to allow for faster access to the data by the processor unit 1702. In some embodiments, the cache memories 1712 and 1714 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 1700 is shown with two processor units, the computing system 1700 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 1700 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

Processor units 1702 and 1704 further comprise memory controller logic (MC) 1720 and 1722. As shown in FIG. 17, MCs 1720 and 1722 control memories 1716 and 1718 coupled to the processor units 1702 and 1704, respectively. The memories 1716 and 1718 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 1720 and 1722 are illustrated as being integrated into the processor units 1702 and 1704, in alternative embodiments, the MCs can be external to a processor unit.

Processor units 1702 and 1704 are coupled to an Input/Output (I/O) subsystem 1730 via point-to-point interconnections 1732 and 1734. The point-to-point interconnection 1732 connects a point-to-point interface 1736 of the processor unit 1702 with a point-to-point interface 1738 of the I/O subsystem 1730, and the point-to-point interconnection 1734 connects a point-to-point interface 1740 of the processor unit 1704 with a point-to-point interface 1742 of the I/O subsystem 1730. Input/Output subsystem 1730 further includes an interface 1750 to couple the I/O subsystem 1730 to a graphics engine 1752. The I/O subsystem 1730 and the graphics engine 1752 are coupled via a bus 1754.

The Input/Output subsystem 1730 is further coupled to a first bus 1760 via an interface 1762. The first bus 1760 can be a Peripheral Component Interconnect Express (PCIe) bus or any other type of bus. Various I/O devices 1764 can be coupled to the first bus 1760. A bus bridge 1770 can couple the first bus 1760 to a second bus 1780. In some embodiments, the second bus 1780 can be a low pin count (LPC) bus. Various devices can be coupled to the second bus 1780 including, for example, a keyboard/mouse 1782, audio I/O devices 1788, and a storage device 1790, such as a hard disk drive, solid-state drive, or another storage device for storing computer-executable instructions (code) 1792 or data. The code 1792 can comprise computer-executable instructions for performing methods described herein. Additional components that can be coupled to the second bus 1780 include communication device(s) 1784, which can provide for communication between the computing system 1700 and one or more wired or wireless networks 1786 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 1702.11 standard and its supplements).

The memory in system 1700 (including caches 1712 and 1714, memories 1716 and 1718, and storage device 1790) can store data and/or computer-executable instructions for executing an operating system 1794 and application programs 1796. Example data includes accelerometer sensor data, inertial measurement unit sensor data, and switch data to be sent to and/or received from one or more network servers or other devices by the system 1700 via the one or more wired or wireless networks 1786, or for use by the system 1700. The system 1700 can also have access to external memory or storage (not shown) such as external hard drives or cloud-based storage.

The operating system 1794 can control the allocation and usage of the components illustrated in FIG. 17 and support the one or more application programs 1796. The application programs 1796 can include common computing system applications as well as other computing applications, such as an immersion cooling system dashboard for remote monitoring and management of a plurality of immersion cooling systems.

The computing system 1700 can support various additional input devices, such as a touchscreen, microphone, trackball, touchpad, trackpad, and one or more output devices, such as one or more speakers or displays. Any of the input or output devices can be internal to, external to, or removably attachable with the system 1700. External input and output devices can communicate with the system 1700 via wired or wireless connections.

The system 1700 can further include at least one input/output port comprising physical connectors (e.g., USB, IEEE 1394 (FireWire), Ethernet, RS-232) and a power supply (e.g., battery). A GNSS receiver can be coupled to a GNSS antenna. The computing system 1700 can further comprise one or more additional antennas coupled to one or more additional receivers, transmitters, and/or transceivers to enable additional functions.

It is to be understood that FIG. 17 illustrates only one example computing system architecture. Computing systems based on alternative architectures can be used to implement technologies described herein. For example, instead of the processors 1702 and 1704 and the graphics engine 1752 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 17. Moreover, the illustrated components in FIG. 17 are not required or all-inclusive, as shown components can be removed and other components added in alternative embodiments.

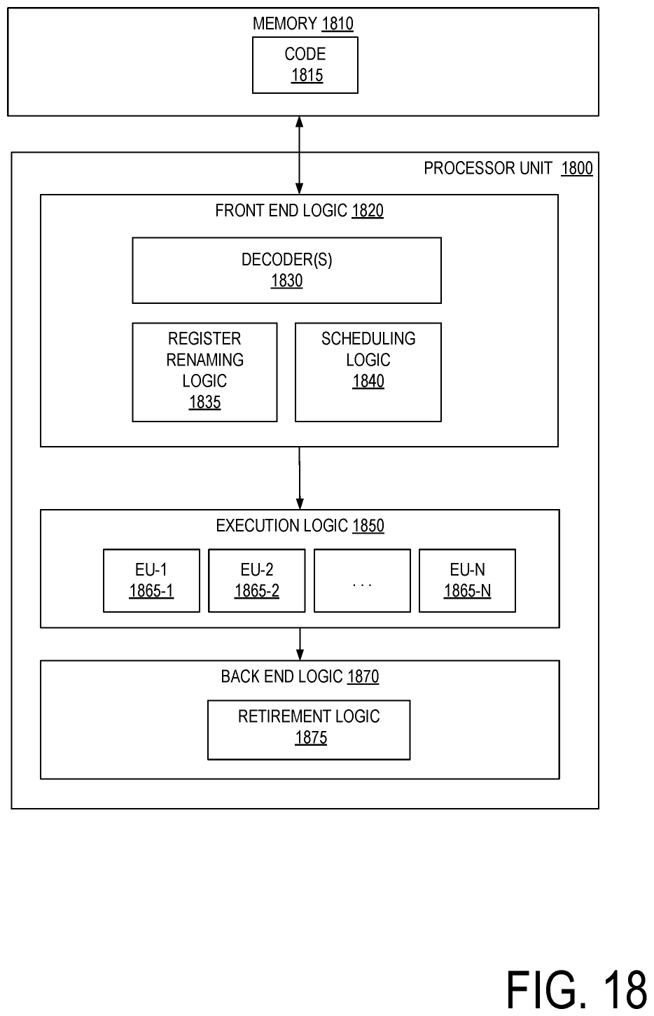

FIG. 18 is a block diagram of an example processor unit to execute computer-executable instructions as part of implementing technologies described herein. The processor unit 1800 can be a single-threaded core or a multithreaded core in that it may include more than one hardware thread context (or “logical processor”) per processor unit.

FIG. 18 also illustrates a memory 1810 coupled to the processor unit 1800. The memory 1810 can be any memory described herein or any other memory known to those of skill in the art. The memory 1810 can store computer-executable instructions 1815 (code) executable by the processor unit 1800.

The processor unit comprises front-end logic 1820 that receives instructions from the memory 1810. An instruction can be processed by one or more decoders 1830. The decoder 1830 can generate as its output a micro-operation such as a fixed width micro-operation in a predefined format, or generate other instructions, microinstructions, or control signals, which reflect the original code instruction. The front-end logic 1820 further comprises register renaming logic 1835 and scheduling logic 1840, which generally allocate resources and queues operations corresponding to converting an instruction for execution.

The processor unit 1800 further comprises execution logic 1850, which comprises one or more execution units (EUs) 1865-1 through 1865-N. Some processor unit embodiments can include a number of execution units dedicated to specific functions or sets of functions. Other embodiments can include only one execution unit or one execution unit that can perform a particular function. The execution logic 1850 performs the operations specified by code instructions. After completion of execution of the operations specified by the code instructions, back-end logic 1870 retires instructions using retirement logic 1875. In some embodiments, the processor unit 1800 allows out of order execution but requires in-order retirement of instructions. Retirement logic 1875 can take a variety of forms as known to those of skill in the art (e.g., re-order buffers or the like).

The processor unit 1800 is transformed during execution of instructions, at least in terms of the output generated by the decoder 1830, hardware registers and tables utilized by the register renaming logic 1835, and any registers (not shown) modified by the execution logic 1850.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an immersion cooling system comprising: an immersion tank located on a base; and a spring damper comprising a first end attached or mounted to the immersion tank and a second end attached to a wall or the base.

Example 2 comprises the immersion cooling system of example 1, wherein the spring damper is a first spring damper and the wall is a first wall, the immersion cooling system further comprising a second spring damper, a first end of the second spring damper attached or mounted to the immersion tank, a second end of the second spring damper attached to a second wall or the base, wherein the first spring damper is oriented substantially orthogonal to the second spring damper.

Example 3 comprises the immersion cooling system of example 2, the immersion cooling system further comprising a third spring damper, a first end of the third spring damper attached to the immersion tank, a second end of the third spring damper to the base or a structure located above the immersion tank, wherein the third spring damper is oriented substantially orthogonal to the first spring damper and the second spring damper.

Example 4 comprises the immersion cooling system of any one of examples 1-3, further comprising a frictional layer between a bottom of the immersion tank and the base.

Example 5 comprises the immersion cooling system of any one of examples 1-3, further comprising a layer of sand located between the immersion tank and the base.

Example 6 comprises the immersion cooling system of any one of examples 1-3, wherein the immersion tank rests on a plurality of ball bearings positioned between the immersion tank and the base.

Example 7 comprises the immersion cooling system of any one of examples 1-6, wherein the first end of the spring damper is mounted to the immersion tank without screws.

Example 8 comprises the immersion cooling system of any one of examples 1-6, wherein the first end of the spring damper is mounted to the immersion tank by preloading of a spring of the spring damper, wherein the spring is preloaded in absence of a seismic event.

Example 9 comprises the immersion cooling system of any one of examples 1-8, wherein the wall is a first wall, the immersion cooling system further comprising a crumple block, a first end of the crumple block attached to the immersion tank, a second end of the crumple block attached to the first wall, a second wall, or the base.

Example 10 comprises the immersion cooling system of example 9, wherein the crumple block comprises foam.

Example 11 comprises the immersion cooling system of example 9, wherein the crumple block comprises a honeycomb structure.

Example 12 comprises the immersion cooling system of any one of examples 1-11, wherein a spring property of the spring damper is controllable by one or more control signals received at the spring damper.

Example 13 comprises the immersion cooling system of any one of examples 1-11, wherein a damping property of the spring damper is controllable by one or more control signals received at the spring damper.

Example 14 comprises the immersion cooling system of example 12 or 13, further comprising: an accelerometer attached to the immersion tank; and a controller to receive sensor data from the accelerometer, generate the one or more control signals based on the sensor data, and transmit the one or more control signals to the spring damper.

Example 15 comprises the immersion cooling system of example 14, wherein the accelerometer is a first accelerometer and the sensor data is first sensor data, the immersion cooling system further comprising a second accelerometer attached to or located in the base, the controller to further receive second sensor data from the second accelerometer and to generate the one or more control signals further based on the second sensor data.

Example 16 comprises the immersion cooling system of any one of examples 1-15, wherein the spring damper is a first spring damper, the immersion cooling system further comprising a second spring damper, a first end of the second spring damper attached to the immersion tank, a second end of the second spring damper attached to the wall or the base, wherein the second spring damper can be enabled or disabled by one or more control signals received at the second spring damper.

Example 17 comprises the immersion cooling system of any one of examples 1-16, further comprising a printed circuit board located in the immersion tank, wherein the immersion tank is at least partially filled with a cooling liquid and the printed circuit board is at least partially immersed in the cooling liquid.

Example 18 is an immersion cooling system comprising: an immersion tank located on a base; one or more accelerometers; a tunable mass; a spring damper comprising a first end attached to the immersion tank and a second end attached to the tunable mass; and a controller to receive sensor data from the one or more accelerometers, generate one or more tunable mass control signals to cause an adjustment to a mass of the tunable mass, and transmit the one or more tunable mass control signals to the tunable mass.

Example 19 comprises the immersion cooling system of example 18, wherein the one or more accelerometers comprise an accelerometer attached to the immersion tank.

Example 20 comprises the immersion cooling system of example 18, wherein the one or more accelerometers comprise an accelerometer attached to or located in the base.

Example 21 comprises the immersion cooling system of any one of examples 18-20, wherein the tunable mass comprises a reservoir, a controllable inlet valve to control addition of liquid to the reservoir, the one or more tunable mass control signals to control the controllable inlet valve.

Example 22 comprises the immersion cooling system of any one of examples 18-20, wherein the tunable mass comprises a reservoir, a controllable outlet valve to control removal of liquid to the reservoir, the one or more tunable mass control signals to control the controllable outlet valve.

Example 23 is an immersion cooling system comprising: an immersion tank located on a base; and an energy absorbing means to absorb energy caused by movement of the immersion tank, the energy absorbing means attached at a first end to the immersion tank and at a second end to a wall or the base.

Example 24 comprises the immersion cooling system of example 23, further comprising a frictional means to allow movement of the immersion tank relative to the base during a seismic event, the frictional means located between the immersion tank and the base.

Example 25 comprises the immersion cooling system of example 23 or 24, wherein the wall is a first wall, the immersion cooling system further comprising a crumpling means to absorb energy caused by movement of the immersion tank relative to the first wall or a second wall by deformation of the crumpling means.

Example 26 is an immersion cooling system comprising: an immersion tank; a compensation tank rigidly attached to the immersion tank; and a liquid mass preservation means to keep a mass of liquid in the immersion tank and the compensation tank substantially constant.

Example 27 is a method comprising: receiving sensor data from one or more accelerometers in an immersion cooling system, the immersion cooling system comprising an immersion tank and a spring damper comprising a first end attached to the immersion tank, a second end of the spring damper attached to a wall or a base, the immersion tank located on the base; determining occurrence of a seismic event based on the sensor data; generating one or more spring damper control signals based on the sensor data; and transmitting the one or more spring damper control signals to the spring damper, the one or more spring damper control signals to cause an adjustment to a spring property and/or a damping property of the spring damper.

Example 28 comprises the method of example 27, wherein the one or more accelerometers comprises an accelerometer attached to the immersion tank.

Example 29 comprises the method of example 27, wherein the one or more accelerometers comprises an accelerometer attached to or located in the base.

Example 30 comprises the method of any one of examples 27-29, the one or more spring damper control signals to cause an adjustment to the spring property of the spring damper.

Example 31 comprises the method of any one of examples 27-29, the one or more spring damper control signals to cause an adjustment to the damping property of the spring damper.

Example 32 comprises the method of any one of examples 27-31, wherein the spring damper is an electromagnetic damper.

Example 33 comprises the method of any one of examples 27-32, wherein the spring damper is a first spring damper and the one or more spring damper control signals are first one or more spring damper control signals, the immersion cooling system further comprising a second spring damper comprising a first end attached to the immersion tank, a second end of the spring damper attached to the wall or the base, the method further comprising: generating one or more second spring damper control signals based on the sensor data; and transmitting the one or more second spring damper control signals to the second spring damper, the one or more second spring damper control signals to cause activation or deactivation of the second spring damper.

Example 34 comprises the method of any one of examples 27-33, further comprising determining a magnitude of the seismic event in response to determining the occurrence of the seismic event, wherein generating the one or more spring damper control signals and transmitting the one or more spring damper control signals to the spring damper are performed in response to determining that the magnitude of the seismic event exceeds a seismic event magnitude threshold.

Example 35 comprises the method of any one of examples 27-34, wherein the spring damper is a first spring damper, the one or more spring damper control signals are one or more first spring damper control signals, and the wall is a first wall, the immersion cooling system further comprising a second spring damper comprising a first end attached to the immersion tank, a second end of the second spring damper attached to a second wall, the first spring damper oriented substantially orthogonal to second spring damper: generating one or more second spring damper control signals based on the sensor data; and transmitting the one or more second spring damper control signals to the second spring damper, the one or more second spring damper control signals to cause a change to a spring property and/or a damping property of the second spring damper.

Example 36 comprises the method of example 35, the immersion cooling system further comprising a third spring damper comprising a first end attached to the immersion tank, a second end of the third spring damper attached to the base or a structure located above the immersion tank, the third spring damper oriented substantially orthogonal to the first spring damper and the second spring damper, the method further comprising: generating one or more third spring damper control signals based on the sensor data; and transmitting the one or more third spring damper control signals to the third spring damper, the one or more third spring damper control signals to cause a change to a spring property and/or a damping property of the third spring damper.

Example 37 is a method comprising: receiving sensor data from one or more accelerometers in an immersion cooling system, the immersion cooling system comprising an immersion tank, a tunable mass, a spring damper comprising a first end attached to the immersion tank, a second end of the spring damper attached the tunable mass; determining occurrence of a seismic event based on the sensor data; generating one or more tunable mass control signals based on the sensor data; and transmitting the one or more tunable mass control signals to the tunable mass, the one or more tunable mass control signals to cause a change to a mass of the tunable mass.

Example 38 comprises the method of example 37, wherein the one or more accelerometers comprises an accelerometer attached to the immersion tank.

Example 39 comprises the method of example 37, wherein the one or more accelerometers comprises an accelerometer attached to or located in a base, the immersion tank located on the base.

Example 40 comprises the method of any one of examples 37-39, wherein the tunable mass comprises a reservoir, the immersion cooling system further comprising a controllable inlet valve to cause liquid to be added to the reservoir and a controllable outlet valve to cause liquid to be removed from the reservoir, the one or more tunable mass controls signals to cause liquid to be added to the reservoir.

Example 41 comprises the method of any one of examples 37-40, wherein the tunable mass comprises a reservoir, the immersion cooling system further comprising a controllable inlet valve to cause liquid to be added to the reservoir and a controllable outlet valve to cause liquid to be removed from the reservoir, the one or more tunable mass controls signals to cause liquid to be removed from the reservoir.

Example 42 comprises the method of any one of examples 37-41, further comprising determining whether a magnitude of the seismic event is greater than a seismic event magnitude threshold, wherein generating the one or more tunable mass control signals and transmitting the one or more tunable mass control signals to the tunable mass are performed if the magnitude of the seismic event exceeds a seismic event magnitude threshold.

Example 43 comprises the method of any one of examples 37-42, wherein the tunable mass is a first tunable mass, the spring damper is a first spring damper, the one or more tunable mass control signals are first one or more tunable mass control signals, the immersion cooling system further comprising a second tunable mass and a second spring damper comprising a first end attached to the immersion tank, a second end of the spring damper attached to a second wall, the first spring damper substantially orthogonal to the second spring damper, the method further comprising: generating one or more second tunable mass control signals based on the sensor data; and transmitting the one or more second tunable mass control signals to the second tunable mass, the one or more second tunable mass control signals to cause a change to a mass of the second tunable mass.

Example 44 comprises the method of example 43, the immersion tank attached to a base, the immersion cooling system further comprising a third tunable mass and a third spring damper comprising a first end attached to the immersion tank, a second end of the third spring damper attached to the base or a structure located above the immersion tank, the third spring damper oriented substantially orthogonal to the first spring damper and the second spring damper, the method further comprising: generating one or more third tunable mass control signals based on the sensor data; and transmitting the one or more third tunable mass control signals to the third tunable mass, the one or more third tunable mass control signals to cause a change to the mass of the third tunable mass.

Example 45 is a method comprising: receiving sensor data from one or more sensors, the sensor data indicating a cooling liquid level in an immersion tank; determining, based on the sensor data, that the cooling liquid level has increased or decreased; generating one or more compensation tank control signals based on the sensor data; and transmitting the one or more compensation tank control signals to a controllable inlet valve and/or a controllable outlet valve, the controllable inlet valve to control addition of liquid to a compensation tank attached to the immersion tank based on the one or more compensation tank control signals, the controllable outlet valve to control removal of liquid from the compensation tank based on the one or more compensation tank control signals.

Example 46 comprises the method of example 45, wherein determining that the cooling liquid level has increased or decreased comprises determining that the cooling liquid level has increased and the one or more compensation tank control signals cause an amount of liquid in the compensation tank to decrease.

Example 47 comprises the method of example 45, wherein determining that cooling liquid level has increased or decreased comprises determining that the cooling liquid level has decreased and the one or more compensation tank control signals cause an amount of liquid in the compensation tank to increase.

Example 48 comprises the method of any one of examples 45-47, wherein determining that the cooling liquid level has increased or decreased comprises determining that the cooling liquid level has increased or decreased by more than a threshold amount from a prior cooling liquid level.

Example 49 comprises the method of any one of examples 45-48, further comprising: receiving, at the controllable inlet valve, the one or more compensation tank control signals; and causing liquid to be added to the compensation tank based on the one or more compensation tank control signals.

Example 50 comprises the method of any one of examples 45-48, further comprising: receiving, at the controllable outlet valve, the compensation tank control signals; and causing liquid to be removed from the compensation tank based on the one or more compensation tank control signals.

Example 51 is an immersion cooling system comprising: a housing pallet; an immersion tank located within the housing pallet, the immersion tank moveable within the housing pallet; a printed circuit board located in the immersion tank; a shutoff switch attached to the housing pallet, wherein activation of the shutoff switch is to cause power to one or more components attached to the printed circuit board to be shut off; and a spring damper comprising a first end attached to the immersion tank, a second end of the spring damper attached to the housing pallet.

Example 52 comprises the immersion cooling system of example 51, wherein the shutoff switch is a push button switch.

Example 53 comprises the immersion cooling system of example 51 or 52, wherein activating the shutoff switch is to further cause power to the printed circuit board to be shut off.

Example 54 comprises the immersion cooling system of example 51, further comprising a controller to receive switch signal data from the shutoff switch and cause power to the one or more components to be shut off based on the switch signal data.

Example 55 comprises the immersion cooling system of any one of examples 51-54, wherein the shutoff switch is a first shutoff switch, the first shutoff switch is attached to a first wall of the housing pallet, the immersion cooling system further comprising a second shutoff switch attached to a second wall of the housing pallet, wherein activation of the second shutoff switch is to cause power to the one or more components to be shut off.

Example 56 comprises the immersion cooling system of example 55, wherein the first wall of the housing pallet is substantially orthogonal to the second wall of the housing pallet.

Example 57 comprises the immersion cooling system of any one of examples 51-54, further comprising a pusher plate attached to a wall of the immersion tank, the pusher plate positioned a distance from the shutoff switch in absence of a seismic event, the pusher plate to activate the shutoff switch when the immersion tank crosses the distance toward the shutoff switch during a seismic event.

Example 58 comprises the immersion cooling system of example 57, wherein the pusher plate is a first pusher plate, the wall of the immersion tank is a first wall of the immersion tank, the distance is a first distance, and the shutoff switch is a first shutoff switch, wherein the immersion cooling system further comprises: a second shutoff switch; and a second pusher plate attached to a second wall of the immersion tank, the second pusher plate positioned on the second wall of the immersion tank, the second pusher plate positioned a second distance from the second shutoff switch in absence of a seismic event, the second pusher plate to activate the second shutoff switch when the immersion tank crosses the second distance toward the second shutoff switch during a seismic event.

Example 59 comprises the immersion cooling system of any one of examples 51-58, wherein the spring damper is a first spring damper, the immersion cooling system further comprising a second spring damper comprising a first end attached to the immersion tank, a second end of the spring damper attached to the housing pallet.

Example 60 comprises the immersion cooling system of example 59, wherein the first end of the first spring damper is attached to a first wall of the immersion tank, the second end of the first spring damper is attached to a first wall of the housing pallet, the first end of the second spring damper is attached to a second wall of the immersion tank, and the second end of the first spring damper is attached to a second wall of the housing pallet.

Example 61 comprises the immersion cooling system of any one of examples 51-61, further comprising: an accelerometer attached to the immersion tank; and a controller to receive sensor data from the accelerometer and to cause the one or more components attached to the printed circuit board to be turned off based on the sensor data.

Example 62 comprises the immersion cooling system of example 61, further comprising an inertial measurement unit comprising the accelerometer.

Example 63 comprises the immersion cooling system of example 61, the controller to wirelessly receive the sensor data.

Example 64 comprises the immersion cooling system of any one of examples 51-63, the immersion tank moveable in the housing pallet via a ball plate attached to a bottom of the immersion tank.

Example 65 comprises the immersion cooling system of any one of examples 51-64, further comprising: a reservoir located outside of the housing pallet; and a controllable valve that controls transfer of cooling liquid between the immersion tank and the reservoir.

Example 66 comprises the immersion cooling system of example 65, wherein activation of the shutoff switch is to further cause transfer of cooling liquid from the immersion tank to the reservoir via the controllable valve.

Example 67 comprises the immersion cooling system of example 65, further comprising: an accelerometer attached to the immersion tank; and a controller to receive sensor data from the accelerometer and to cause transfer of cooling liquid from the immersion tank to the reservoir.

Example 68 is an immersion cooling system comprising: a housing pallet; an immersion tank located within the housing pallet, the immersion tank moveable within the housing pallet; a printed circuit board located in the immersion tank; an energy absorbing means to absorb energy caused by movement of the immersion tank within the housing pallet and dampen the movement of the immersion tank, the energy absorbing means attached at a first end to the immersion tank and at a second end to the housing pallet; and a shutoff means to cause power to be shut off to one or more components attached to the printed circuit board.

Example 69 comprises the immersion cooling system of example 68, further comprising a reservoir and a liquid transfer means to transfer cooling liquid from the immersion tank to the reservoir during a seismic event.

Example 70 is a method comprising: receiving switch data from one or more shutoff switches attached to a housing pallet, the housing pallet housing an immersion tank, wherein for individual of the one or more shutoff switches, the immersion tank is located a distance from the individual shutoff switch in absence of a seismic event and the immersion tank is able to activate the individual shutoff switch by crossing the distance during a seismic event; determining that one of the one or more shutoff switches has been activated based on the switch data; and shutting off power to one or more components attached to a printed circuit board located within the immersion tank in response to determining that one of the one or more shutoff switches has been activated.

Example 71 comprises the method of example 70, further comprising, after shutting off power to the one or more components, causing power for the one or more components to be turned on after a predetermined period.

Example 72 comprises the method of example 70 or 71, wherein a first shutoff switch of the one or more shutoff switches is attached to a first wall of the housing pallet and a second shutoff switch is attached to a second wall of the housing pallet.

Example 73 comprises the method of example 72, wherein a third shutoff switch of the one or more shutoff switches is attached to a third wall of the housing pallet and a fourth shutoff switch is attached to a fourth wall of the housing pallet.

Example 74 comprises the method of any one of examples 70-73, further comprising causing cooling liquid to transfer from the immersion tank to a reservoir in response to determining that one of the one or more shutoff switches has been activated, the reservoir located outside of the housing pallet.

Example 75 comprises the method of example 74, further comprising, after causing cooling liquid to be transferred from the immersion tank to the reservoir, causing cooling liquid to transfer from the reservoir to the immersion tank after a predetermined period.

Example 76 is a method comprising: receiving sensor data from an accelerometer attached to an immersion tank; determining occurrence of a seismic event based on the sensor data; and shutting off power to one or more components attached to a printed circuit located within the immersion tank.

Example 77 comprises the method of example 76, further comprising, after shutting off power to the one or more components, causing power for the one or more components to be turned on after a predetermined period.

Example 78 comprises the method of example 76 or 77, further comprising determining that a magnitude of the seismic event exceeds a seismic event magnitude threshold, wherein shutting off power to the one or more components occurs in response to determining that the magnitude of the seismic event exceeds the seismic event magnitude threshold.

Example 79 comprises the method of any one of examples 76-78, further comprising causing cooling liquid in the immersion tank to transfer from the immersion tank to a reservoir in response to determining occurrence of a seismic event, wherein the immersion tank is located within a housing pallet and the reservoir is located outside of the housing pallet.

Example 80 comprises the method of example 79, further comprising, after causing cooling liquid to be transferred from the immersion tank to the reservoir causing, causing cooling liquid to be transferred from the reservoir to the immersion tank after a predetermined period.

Example 81 comprises the method of example 79, further comprising, after causing cooling liquid to be transferred from the immersion tank to the reservoir, causing power to be turned on for the one or more components after a predetermined period.

Example 82 comprises the method of example 79, further comprising: determining an end of the seismic event based on the sensor data; and causing cooling liquid to transfer from the reservoir to the immersion tank in response to determining the end of the seismic event.

Example 83 comprises the method of example 79, further comprising: determining an end of the seismic event based on the sensor data; and causing power to be turned on for the one or more components in response to determining the end of the seismic event.

Example 84 comprises the method of any one of examples 76-83, wherein determining occurrence of a seismic event based on the sensor data comprising utilizing a trained machine learning model to determine the occurrence of a seismic event.

Example 85 comprise one or more computer-readable media having instructions stored there that, when executed, cause one or more processing units to perform the method of any one of examples 27-51 or 70-84.

1. An immersion cooling system comprising:
an immersion tank located on a base; and
a spring damper comprising a first end attached or mounted to the immersion tank and a second end attached to a wall or the base.

2. The immersion cooling system of claim 1, wherein the spring damper is a first spring damper and the wall is a first wall, the immersion cooling system further comprising a second spring damper, a first end of the second spring damper attached or mounted to the immersion tank, a second end of the second spring damper attached to a second wall or the base, wherein the first spring damper is oriented substantially orthogonal to the second spring damper.

3. The immersion cooling system of claim 1, wherein the first end of the spring damper is mounted to the immersion tank by preloading of a spring of the spring damper, wherein the spring is preloaded in absence of a seismic event.

4. The immersion cooling system of claim 1, wherein the wall is a first wall, the immersion cooling system further comprising a crumple block, a first end of the crumple block attached to the immersion tank, a second end of the crumple block attached to the first wall, a second wall, or the base.

5. The immersion cooling system of claim 1, wherein a spring property or a damping property of the spring damper is controllable by one or more control signals received at the spring damper.

6. The immersion cooling system of claim 5, further comprising:
an accelerometer attached to the immersion tank; and
a controller to receive sensor data from the accelerometer, generate the one or more control signals based on the sensor data, and transmit the one or more control signals to the spring damper.

7. The immersion cooling system of claim 6, wherein the accelerometer is a first accelerometer and the sensor data is first sensor data, the immersion cooling system further comprising a second accelerometer attached to or located in the base, the controller to further receive second sensor data from the second accelerometer and to generate the one or more control signals further based on the second sensor data.

8. The immersion cooling system of claim 1, wherein the spring damper is a first spring damper, the immersion cooling system further comprising a second spring damper, a first end of the second spring damper attached to the immersion tank, a second end of the second spring damper attached to the wall or the base, wherein the second spring damper can be enabled or disabled by one or more control signals received at the second spring damper.

9. A method comprising:
receiving sensor data from one or more accelerometers in an immersion cooling system, the immersion cooling system comprising an immersion tank and a spring damper comprising a first end attached to the immersion tank, a second end of the spring damper attached to a wall or a base, the immersion tank located on the base;
determining occurrence of a seismic event based on the sensor data;
generating one or more spring damper control signals based on the sensor data; and
transmitting the one or more spring damper control signals to the spring damper, the one or more spring damper control signals to cause an adjustment to a spring property and/or a damping property of the spring damper.

10. The method of claim 9, wherein the one or more accelerometers comprises an accelerometer attached to the immersion tank and/or an accelerometer attached to or located in the base.

11. The method of claim 9, the one or more spring damper control signals to cause an adjustment to the spring property and/or the damping property of the spring damper.

12. The method of claim 9, wherein the spring damper is a first spring damper and the one or more spring damper control signals are first one or more spring damper control signals, the immersion cooling system further comprising a second spring damper comprising a first end attached to the immersion tank, a second end of the spring damper attached to the wall or the base, the method further comprising:
generating one or more second spring damper control signals based on the sensor data; and
transmitting the one or more second spring damper control signals to the second spring damper, the one or more second spring damper control signals to cause activation or deactivation of the second spring damper.

13. The method of claim 9, further comprising determining a magnitude of the seismic event in response to determining the occurrence of the seismic event, wherein generating the one or more spring damper control signals and transmitting the one or more spring damper control signals to the spring damper are performed in response to determining that the magnitude of the seismic event exceeds a seismic event magnitude threshold.

14. An immersion cooling system comprising:
a housing pallet;
an immersion tank located within the housing pallet, the immersion tank moveable within the housing pallet;
a printed circuit board located in the immersion tank;
a shutoff switch attached to the housing pallet, wherein activation of the shutoff switch is to cause power to one or more components attached to the printed circuit board to be shut off; and
a spring damper comprising a first end attached to the immersion tank, a second end of the spring damper attached to the housing pallet.

15. The immersion cooling system of claim 14, wherein activating the shutoff switch is to further cause power to the printed circuit board to be shut off.

16. The immersion cooling system of claim 14, further comprising a controller to receive switch signal data from the shutoff switch and cause power to the one or more components to be shut off based on the switch signal data.

17. The immersion cooling system of claim 14, further comprising a pusher plate attached to a wall of the immersion tank, the pusher plate positioned a distance from the shutoff switch in absence of a seismic event, the pusher plate to activate the shutoff switch when the immersion tank crosses the distance toward the shutoff switch during a seismic event.

18. The immersion cooling system of claim 17, wherein the pusher plate is a first pusher plate, the wall of the immersion tank is a first wall of the immersion tank, the distance is a first distance, and the shutoff switch is a first shutoff switch, wherein the immersion cooling system further comprises:
a second shutoff switch; and
a second pusher plate attached to a second wall of the immersion tank, the second pusher plate positioned on the second wall of the immersion tank, the second pusher plate positioned a second distance from the second shutoff switch in absence of a seismic event, the second pusher plate to activate the second shutoff switch when the immersion tank crosses the second distance toward the second shutoff switch during a seismic event.

19. The immersion cooling system of claim 14, further comprising:
an accelerometer attached to the immersion tank; and
a controller to receive sensor data from the accelerometer and to cause the one or more components attached to the printed circuit board to be turned off based on the sensor data.

20. The immersion cooling system of claim 14, further comprising:
a reservoir located outside of the housing pallet; and
a controllable valve that controls transfer of cooling liquid between the immersion tank and the reservoir, wherein activation of the shutoff switch is to further cause transfer of cooling liquid from the immersion tank to the reservoir via the controllable valve.
